(19) United States
(12) Patent Application Publication
(10) Pub. No.: US 2026/0133494 A1
(43) Pub. Date: May 14, 2026

(54) RESIST UNDERLAYER FILM-FORMING COMPOSITION

(71) Applicant: NISSAN CHEMICAL CORPORATION, Tokyo (JP)

(72) Inventors: Tomotada HIROHARA, Toyama-shi (JP); Hiroto OGATA, Toyama-shi (JP); Mamoru TAMURA, Toyama-shi (JP)

(73) Assignee: NISSAN CHEMICAL CORPORATION, Tokyo (JP)

(21) Appl. No.: 19/116,430

(22) PCT Filed: Oct. 3, 2023
(86) PCT No.: PCT/JP2023/036038

§ 371 Date: Mar. 28, 2025

(30) Foreign Application Priority Data
Oct. 4, 2022 (JP) 2022-160267

(51) Int. Cl. G03F 7/09; C08G 59/24; C08G 59/62; G03F 7/00; G03F 7/36; H10P 50/00

(52) U.S. Cl. CPC G03F 7/094; C08G 59/245; C08G 59/621; G03F 7/36; H10P 50/73; G03F 7/70033

(57) ABSTRACT

A resist underlayer film-forming composition for use in EB or EUV lithography, the resist underlayer film-forming composition containing a polymer having a structure represented by formula (1) below, and a solvent.

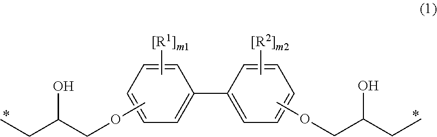

In formula (1), R¹ and R² each independently represent an alkyl group which has 1 to 6 carbon atoms and may be substituted with a halogen atom, or a halogen atom, m1 and m2 each independently represent an integer of 0 to 4, when there are two or more R¹'s, the two or more R¹'s may be the same or different, when there are two or more R²'s, the two or more R²'s may be the same or different, and * represents a bond.

### TECHNICAL FIELD

The present invention relates to a resist underlayer film-forming composition, a resist underlayer film, a laminate, a method for producing a semiconductor element, and a pattern forming method.

### BACKGROUND ART

Conventionally, microfabrication by lithography using a resist composition has been performed in the production of a semiconductor device. The microfabrication is a processing method of forming microrelief corresponding to a photoresist pattern on a substrate surface by forming a thin film of a photoresist composition on a semiconductor substrate such as a silicon wafer, irradiating the thin film with an active ray such as an ultraviolet ray through a mask pattern on which a device pattern is drawn, developing the thin film, and etching the substrate using the obtained photoresist pattern as a protective film. In recent years, the degree of integration of semiconductor devices has been increased, and also as the active ray to be used, in addition to i-line (wavelength: 365 nm), KrF excimer laser (wavelength: 248 nm), and ArF excimer laser (wavelength: 193 nm) that have been conventionally used, practical application of EUV light (wavelength: 13.5 nm) or an electron beam (EB) has been studied for the most advanced microfabrication. Along with this, poor resist pattern formation due to an influence of a semiconductor substrate or the like becomes a major problem. Therefore, in order to solve this problem, a method of providing a resist underlayer film between a resist and a semiconductor substrate has been widely studied.

Patent Literature 1 discloses an underlayer film-forming composition for use in lithography containing a naphthalene ring having a halogen atom. Patent Literature 2 discloses a halogenated antireflection film. Patent Literature 3 discloses a resist underlayer film-forming composition.

### CITATION LIST

### Patent Literature

Patent Literature 1: WO 2006/003850 A
Patent Literature 2: JP 2005-526270 A
Patent Literature 3: WO 2020/111068 A

### SUMMARY OF INVENTION

### Technical Problem

In semiconductor device processing, in order to improve productivity, an increase in sensitivity of a resist has been required as one of the methods for shortening an exposure time. In particular, in semiconductor device processing using the most advanced electron beam (EB) or extreme ultraviolet (EUV) lithography technology, since the EB irradiation time or the EUV exposure time affects productivity, this requirement is strong.

The present invention has been made in view of the above circumstances, and an object of the present invention is to provide a resist underlayer film-forming composition capable of forming a resist underlayer film capable of increasing the sensitivity of a resist, and a resist underlayer film, a laminate, a method for producing a semiconductor element, and a pattern forming method using the resist underlayer film-forming composition.

### Solution to Problem

As a result of intensive studies to solve the above-mentioned problems, the present inventors found that the above-mentioned problems can be solved, and completed the present invention having the following gist.

That is, the present invention includes the following aspects.

[1] A resist underlayer film-forming composition for use in EB or EUV lithography, the resist underlayer film-forming composition containing
a polymer having a structure represented by formula (1) below, and a solvent:

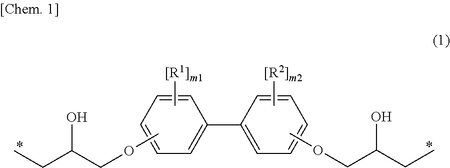

wherein R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different, and
* represents a bond.

[2] The resist underlayer film-forming composition according to [1], wherein the polymer has a repeating unit represented by formula (1-1) below as a repeating unit having a structure represented by formula (1):

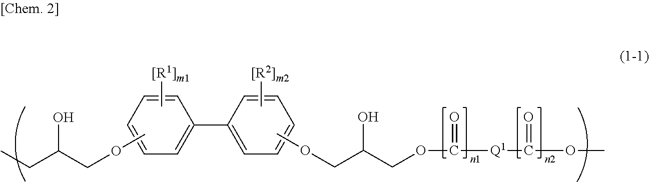

wherein R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different,
Q¹ represents a divalent organic group having an aromatic hydrocarbon ring, and
n1 and n2 each independently represent 0 or 1.

[3] The resist underlayer film-forming composition according to [2], wherein the Q¹ is represented by formula (1-1-1) below:

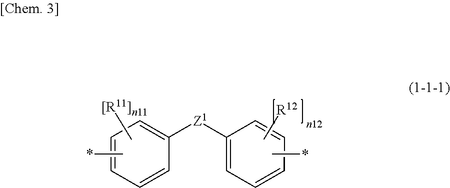

wherein Z¹ represents a single bond, an alkylene group which has 1 to 6 carbon atoms and may be substituted with a halogen atom, or a sulfonyl group,
R¹¹ and R¹² each independently represent an alkyl group which has 1 to 13 carbon atoms and may be substituted with a halogen atom, a hydroxy group, a methoxy group, a thiol group, an acetyl group, a nitro group, an allyl group, a phenyl group, a naphthyl group, or a halogen atom,
n11 and n12 each independently represent an integer of 0 to 4,
when there are two or more R¹¹'s, the two or more R¹¹'s may be the same or different, and
when there are two or more R¹²'s, the two or more R¹²'s may be the same or different.

[4] The resist underlayer film-forming composition according to any one of [1] to [3], wherein m1 and m2 are 1, and R¹ and R² are methyl groups.

[5] The resist underlayer film-forming composition according to any one of [1] to [4], further containing a crosslinking agent.

[6] The resist underlayer film-forming composition according to [5], wherein the crosslinking agent is a compound having two or more structures represented by formula (C) below:

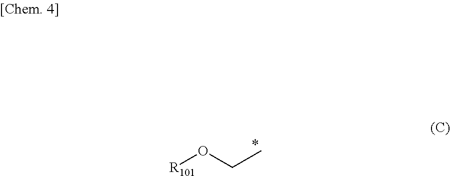

wherein R₁₀₁ represents a hydrogen atom, an alkyl group having 1 to 4 carbon atoms, or an alkoxyalkyl group having 2 to 6 carbon atoms, and * represents a bond.

[7] A resist underlayer film which is a cured product of the resist underlayer film-forming composition according to any one of [1] to [6].

[8] A laminate, including:
a semiconductor substrate; and
the resist underlayer film according to [7].

[9] A method for producing a semiconductor element, the method including steps of:
forming a resist underlayer film on a semiconductor substrate using the resist underlayer film-forming composition according to any one of [1] to [6]; and
forming a resist film on the resist underlayer film.

[10] A pattern forming method, comprising steps of:
forming a resist underlayer film on a semiconductor substrate using the resist underlayer film-forming composition according to any one of [1] to [6];
forming a resist film on the resist underlayer film;
irradiating the resist film with EB or EUV, and then developing the resist film to obtain a resist pattern; and
etching the resist underlayer film using the resist pattern as a mask.

### Advantageous Effects of Invention

According to the present invention, it is possible to provide a resist underlayer film-forming composition capable of forming a resist underlayer film capable of increasing the sensitivity of a resist, and a resist underlayer film, a laminate, a method for producing a semiconductor element, and a pattern forming method using the resist underlayer film-forming composition.

### DESCRIPTION OF EMBODIMENTS

### (Resist Underlayer Film-Forming Composition)

The resist underlayer film-forming composition of the present invention is a resist underlayer film-forming composition for use in electron beam (EB) or extreme ultraviolet (EUV) lithography.

The resist underlayer film-forming composition contains a polymer (A) and a solvent.

### <Polymer (A)>

The polymer (A) has a structure represented by formula (1) below.

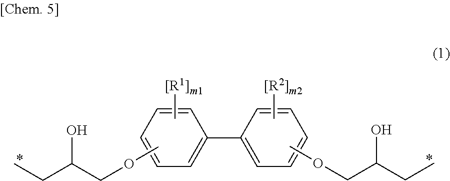

In formula (1), R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different, and
* represents a bond.

Examples of the alkyl group which has 1 to 6 carbon atoms and may be substituted with a halogen atom in R¹ and R² include an alkyl group having 1 to 6 carbon atoms.

Examples of the alkyl group having 1 to 6 carbon atoms include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Among them, an alkyl group having 1 to 4 carbon atoms is preferred, a methyl group and an ethyl group is more preferred, and a methyl group is particularly preferred.

In formula (1-1), m1 and m2 are preferably 1, and R¹ and R² are preferably methyl groups.

Examples of the structure represented by formula (1) include the following structures.

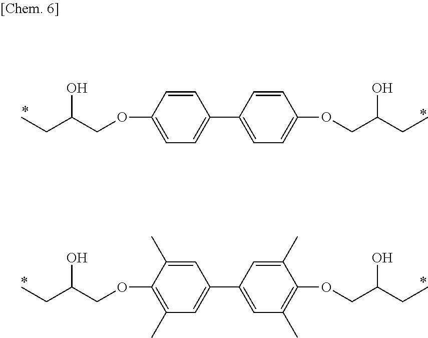

In the formula, * represents a bond.

The bond * in the structure represented by formula (1) is bonded to, for example, a heteroatom. Examples of the heteroatom include an oxygen atom and a nitrogen atom.

The polymer (A) may have, as a repeating unit having a structure represented by formula (1), at least one of a repeating structure represented by formula (1-1) below and a repeating unit represented by formula (1-2) below.

The polymer (A) preferably has a repeating unit represented by formula (1-1) below as a repeating unit having a structure represented by formula (1).

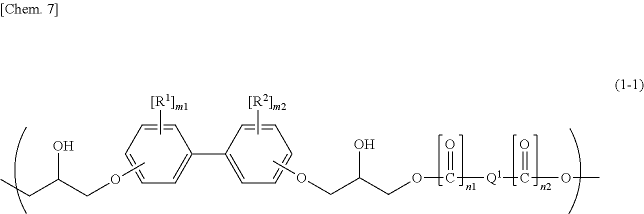

In formula (1-1), R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different,
Q¹ represents a divalent organic group having an aromatic hydrocarbon ring, and
n1 and n2 each independently represent 0 or 1.
Q¹ in formula (1-1) is preferably represented by formula (1-1-1) below.

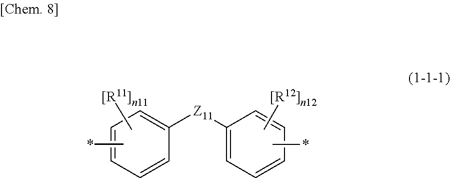

In formula (1-1-1), Z¹ represents a single bond, an alkylene group which has 1 to 6 carbon atoms and may be substituted with a halogen atom, or a sulfonyl group,
R¹¹ and R¹² each independently represent an alkyl group which has 1 to 13 carbon atoms and may be substituted with a halogen atom, a hydroxy group, a methoxy group, a thiol group, an acetyl group, a nitro group, an allyl group, a phenyl group, a naphthyl group, or a halogen atom,
n11 and n12 each independently represent an integer of 0 to 4,
when there are two or more R¹¹'s, the two or more R¹¹'s may be the same or different, and
when there are two or more R¹²'s, the two or more R¹²'s may be the same or different.

Z¹ in formula (1-1) is preferably, for example, an alkylene group which has 1 to 6 carbon atoms and may be substituted with a halogen atom, or a sulfonyl group.

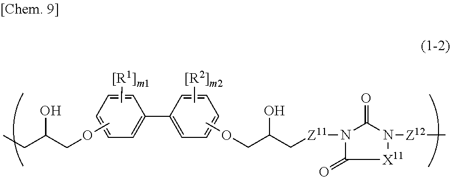

In formula (1-2), R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different,
X¹¹ represents a divalent group represented by any one of formulae (1-2-1) to (1-2-3) below, and Z¹¹ and Z¹² each independently represent a single bond or a divalent group represented by formula (1-2-4) below.

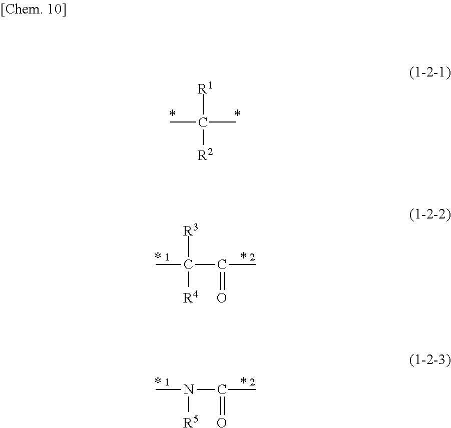

In formulae (1-2-1) to (1-2-3), R¹ to R⁵ each independently represent a hydrogen atom, an alkyl group which has 1 to 10 carbon atoms and may be interrupted by an oxygen atom or a sulfur atom, an alkenyl group which has 2 to 10 carbon atoms and may be interrupted by an oxygen atom or a sulfur atom, an alkynyl group which has 2 to 10 carbon atoms and may be interrupted by an oxygen atom or a sulfur atom, a benzyl group, or a phenyl group, and the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R¹ and R² may be bonded to each other to form a ring having 3 to 6 carbon atoms, R³ and R⁴ may be bonded to each other to form a ring having 3 to 6 carbon atoms,
* represents a bond, *1 represents a bond bonded to a carbon atom in formula (1-2), and *2 represents a bond bonded to a nitrogen atom in formula (1-2).

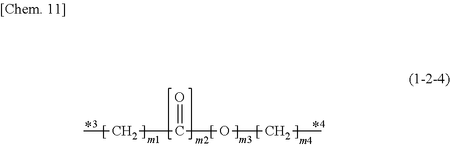

In formula (1-2-4), m1 is an integer of 0 to 4, m2 is 0 or 1, m3 is 0 or 1, and m4 is an integer of 0 to 2, however, when m3 is 1, m1 and m2 are not 0 at the same time, *3 represents a bond bonded to a nitrogen atom in formula (1-2), and *4 represents a bond.

In the present description, examples of the halogen atom include a fluorine atom, a chlorine atom, a bromine atom, and an iodine atom.

In the present description, the alkyl group is not limited to a linear form, and may be branched or cyclic. Examples of the linear or branched alkyl group include a methyl group, an ethyl group, an isopropyl group, a tert-butyl group, and a n-hexyl group. Examples of the cyclic alkyl group (cycloalkyl group) include a cyclobutyl group, a cyclopentyl group, and a cyclohexyl group.

In the present description, examples of the alkoxy group include a methoxy group, an ethoxy group, a n-pentyloxy group, and an isopropoxy group.

In the present description, examples of the alkylthio group include a methylthio group, an ethylthio group, a n-pentylthio group, and an isopropylthio group.

In the present description, examples of the alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, and a 2-methyl-2-propenyl group.

In the present description, examples of the alkynyl group include a group in which a double bond of an alkenyl group listed in the above “alkenyl group” is replaced with a triple bond.

In the present description, examples of the alkenyloxy group include a vinyloxy group, a 1-propenyloxy group, a 2-n-propenyloxy group (allyloxy group), a 1-n-butenyloxy group, and a prenyloxy group.

In the present description, examples of the alkynyloxy group include a 2-propynyloxy group, a 1-methyl-2-propynyloxy group, a 2-methyl-2-propynyloxy group, a 2-butynyloxy group, and a 3-butynyloxy group.

In the present description, examples of the acyl group include an acetyl group and a propionyl group.

In the present description, examples of the aryloxy group include a phenoxy group and naphthyloxy.

In the present description, examples of the arylcarbonyl group include a phenylcarbonyl group.

In the present description, examples of the aralkyl group include a benzyl group and a phenethyl group.

In the present description, examples of the alkylene group include a methylene group, an ethylene group, a 1,3-propylene group, a 2,2-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, and a 1,10-decylene group.

Examples of the alkyl group which has 1 to 10 carbon atoms and may be interrupted by an oxygen atom or a sulfur atom in R¹ to R⁵ in formulae (1-2-1) to (1-2-3) include an alkyl group having 1 to 10 carbon atoms, an alkoxy group having 1 to 10 carbon atoms, an alkoxyalkyl group having 2 to 10 carbon atoms, an alkoxyalkoxyalkyl group having 3 to 10 carbon atoms, an alkylthio group having 1 to 10 carbon atoms, and an alkylthioalkyl group having 2 to 10 carbon atoms.

The alkyl group which has 1 to 10 carbon atoms and may be interrupted by an oxygen atom or a sulfur atom may contain two or more oxygen atoms or sulfur atoms.

Examples of the structure represented by the following formula in formula (1-1) include the following structures.

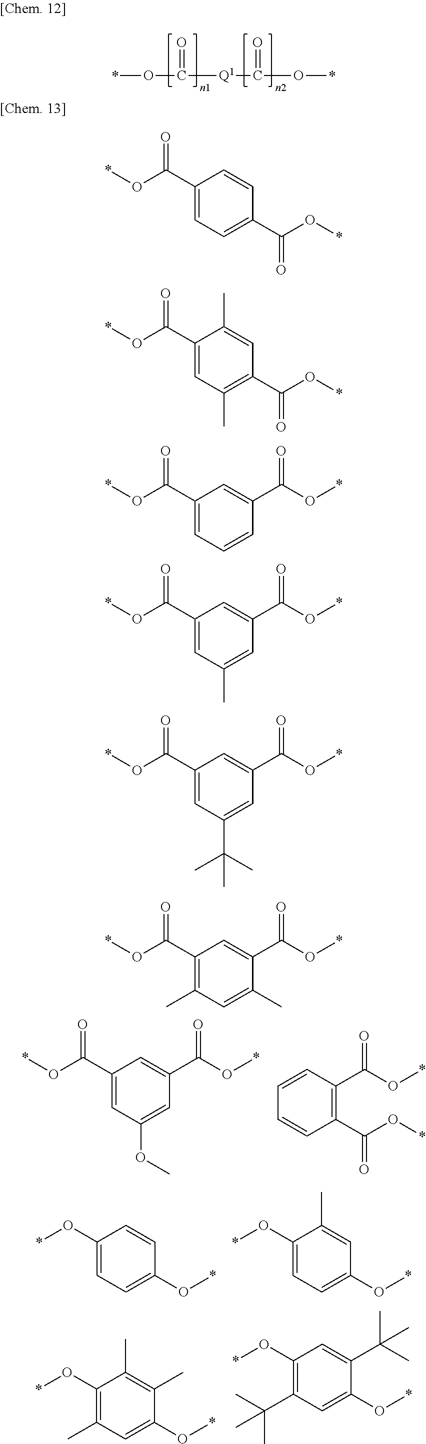

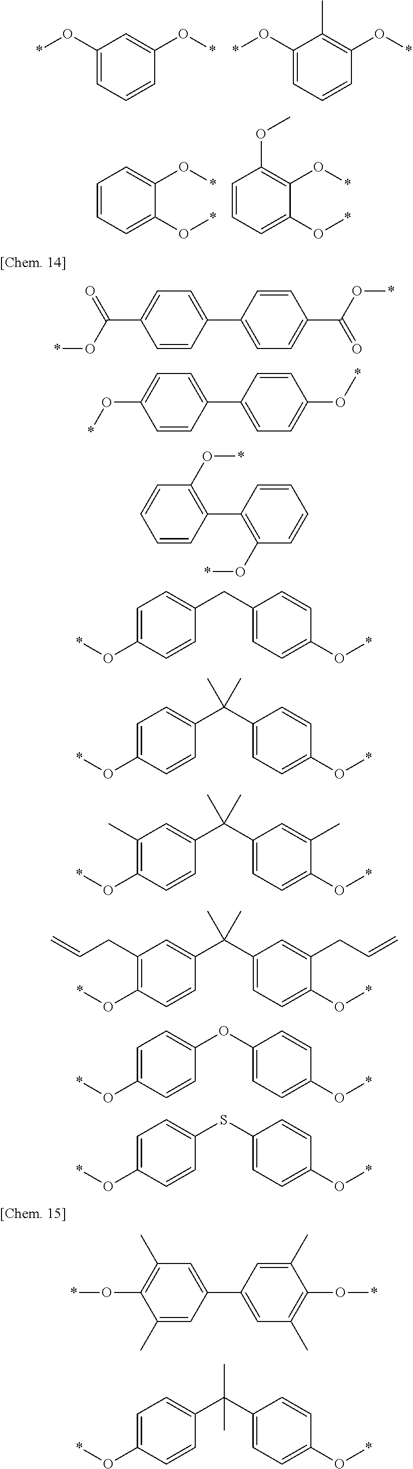

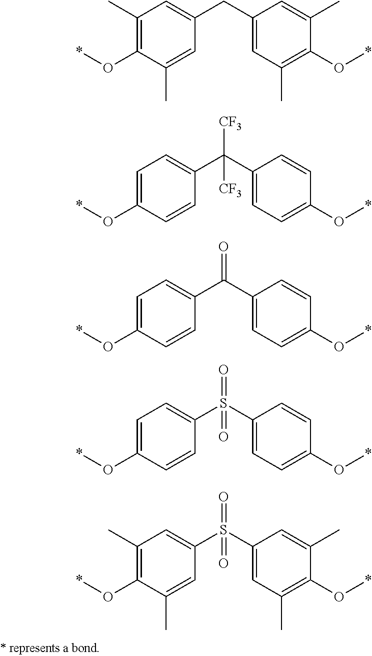 [SMILES: *Oc1c(C)cc(Cc2cc(C)c(O*)c(C)c2)cc1C ; *Oc1ccc(C(c2ccc(O*)cc2)(C(F)(F)F)C(F)(F)F)cc1 ; *Oc1ccc(C(=O)c2ccc(O*)cc2)cc1 ; *Oc1ccc(S(=O)(=O)c2ccc(O*)cc2)cc1 ; *Oc1c(C)cc(S(=O)(=O)c2cc(C)c(O*)c(C)c2)cc1C]

Examples of the structure represented by the following formula in formula (1-2) include the following structures.

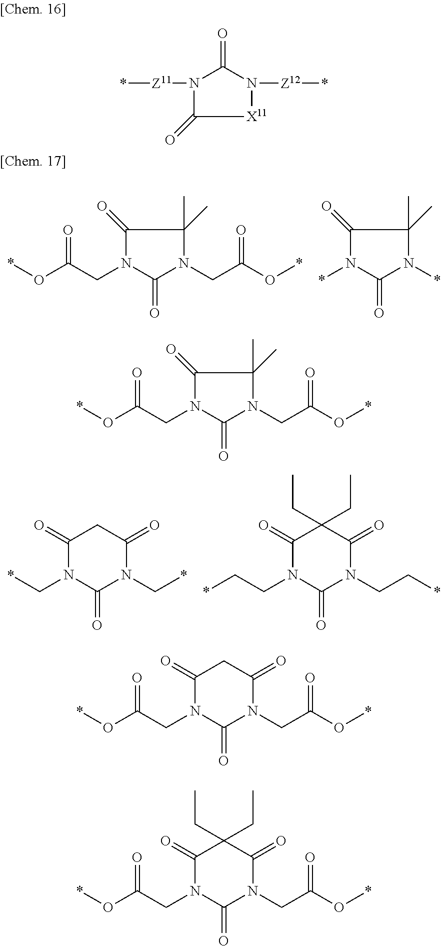

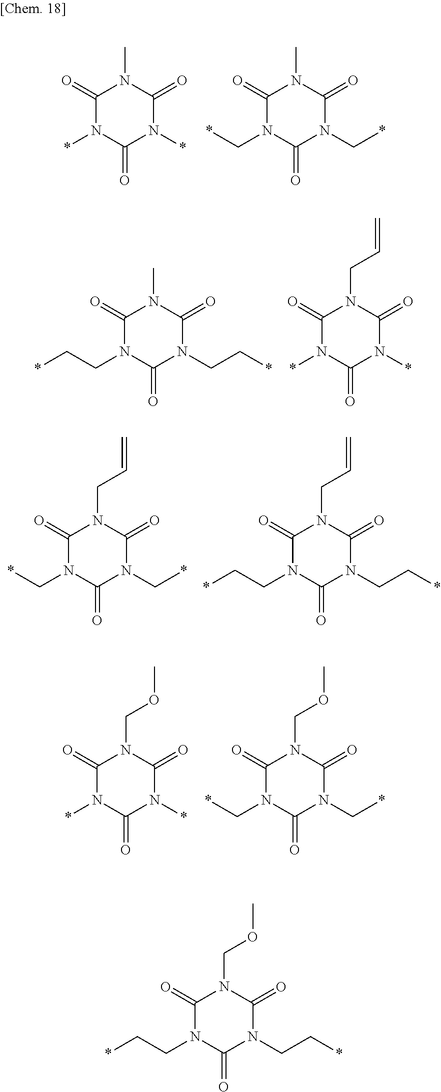

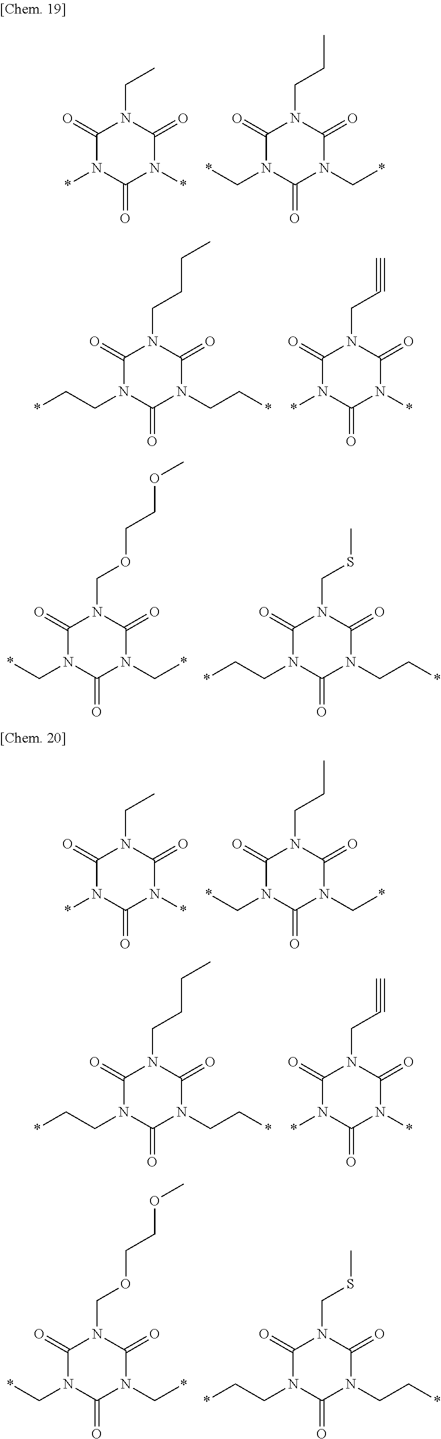

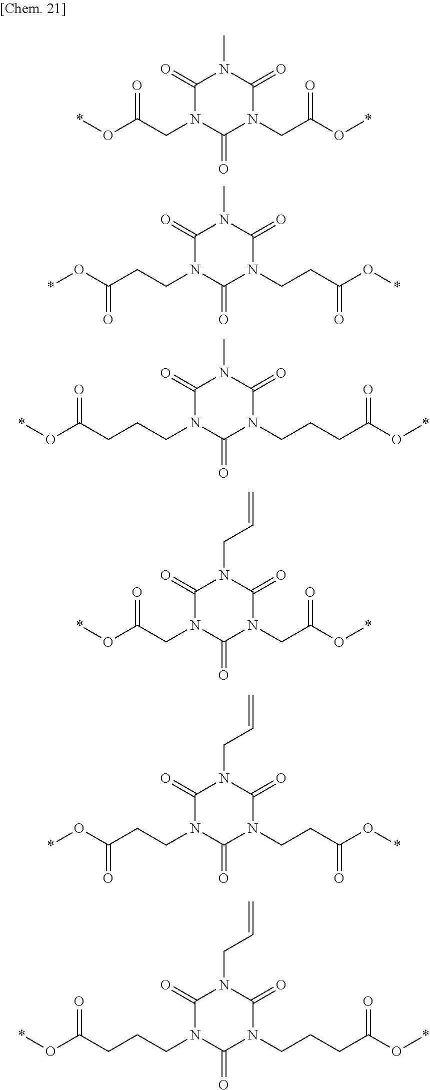

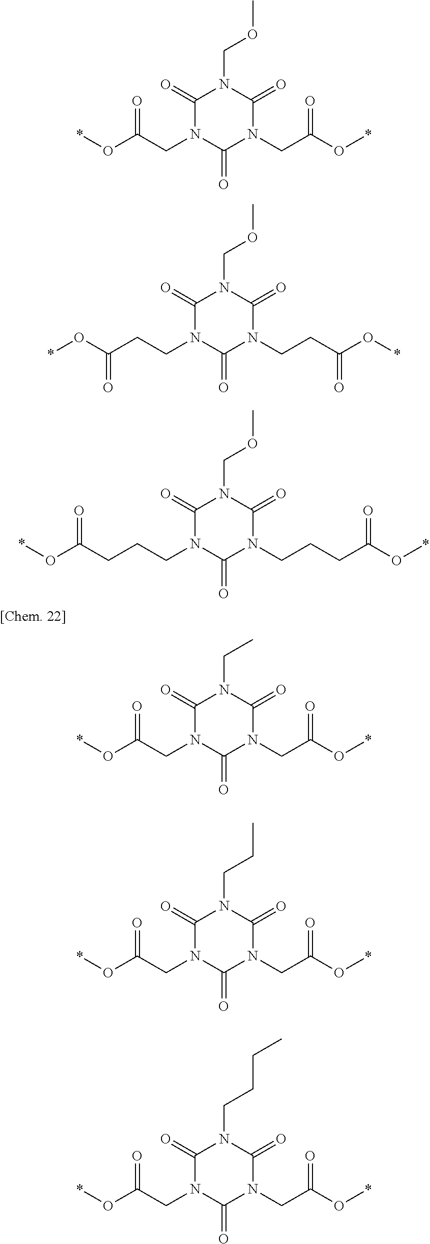

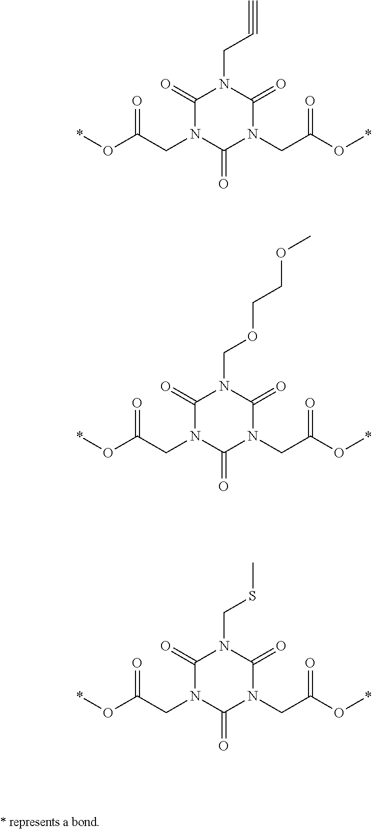 [SMILES: *OC(=O)Cn1c(=O)n(CC#C)c(=O)n(CC(=O)O*)c1=O ; *OC(=O)Cn1c(=O)n(COCCOC)c(=O)n(CC(=O)O*)c1=O ; *OC(=O)Cn1c(=O)n(CSC)c(=O)n(CC(=O)O*)c1=O]

The polymer (A) may have a structure represented by formula (E) below. The structure represented by formula (E) is, for example, located at an end (one end or both ends) of the polymer (A).

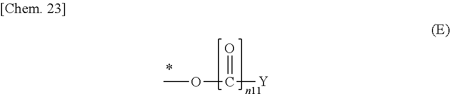

In formula (E), Y represents a monovalent group, n11 represents 0 or 1, and * represents a bond.

Examples of the monovalent group in Y in formula (E) include a monovalent organic group having 1 to 30 carbon atoms.

Examples of Y in formula (E) include a monovalent residue obtained by removing one hydrogen atom from an aliphatic ring which may be substituted with a substituent, and a monovalent aromatic group which may be substituted with a substituent.

Examples of the substituent include a halogen atom, a hydroxy group, an alkyl group having 1 to 6 carbon atoms, and an alkoxy group having 1 to 6 carbon atoms.

Examples of the aromatic group in the monovalent aromatic group which may be substituted with a substituent include an aromatic hydrocarbon group. Examples of the aromatic hydrocarbon group include a phenyl group, a naphthyl group, and an anthracenyl group.

Examples of the compound that gives the structure represented by formula (E) to the polymer (A) include a compound represented by formula (EA) below.

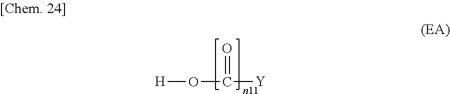

In formula (EA), Y and n11 have the same meanings as Y and n11 in formula (E), respectively.

Examples of the compound represented by formula (EA) include the following compounds.

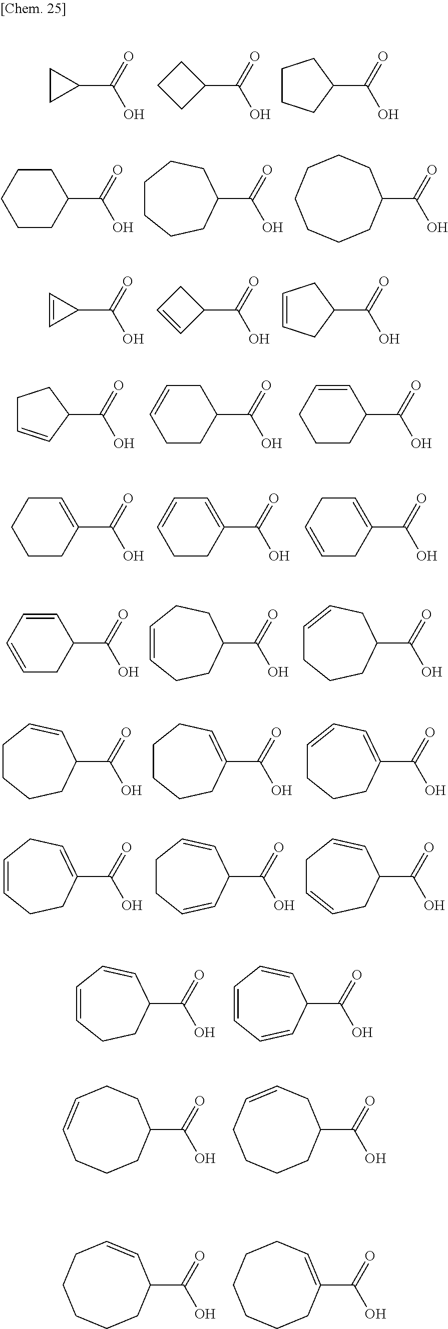

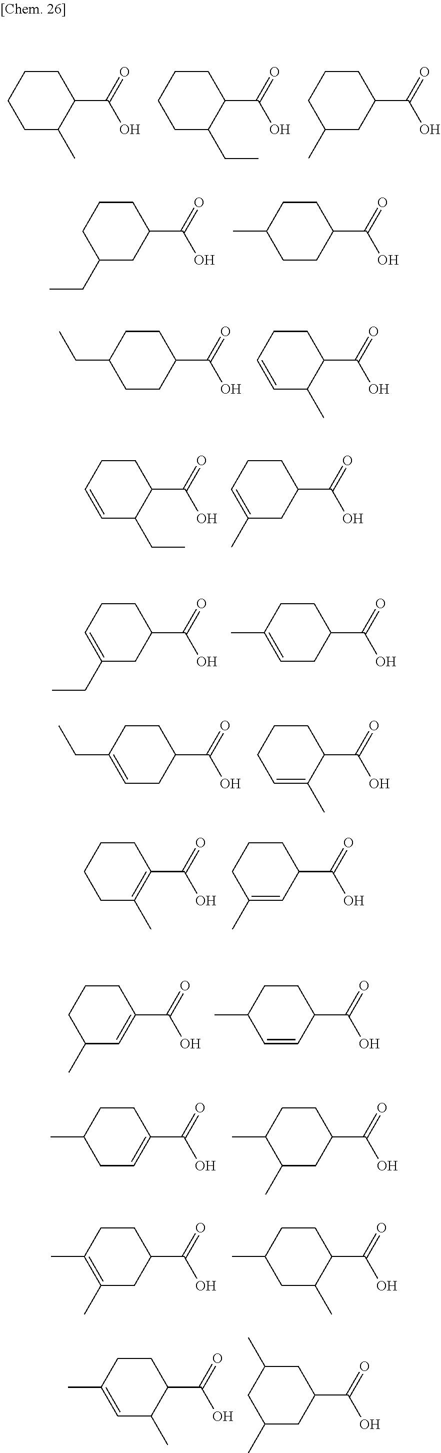

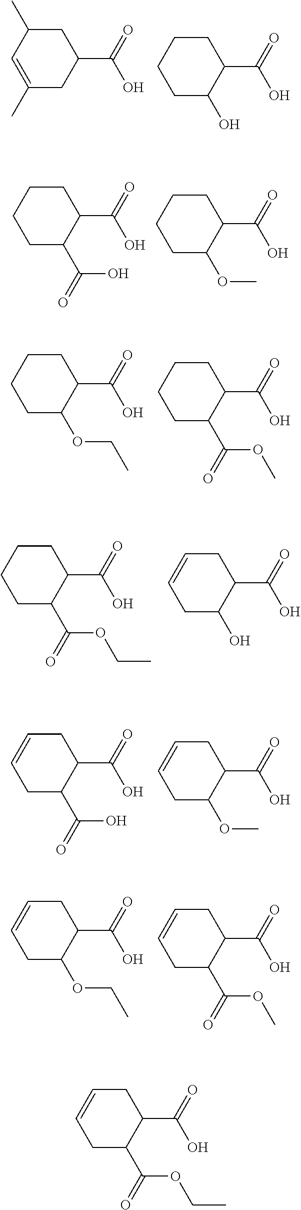

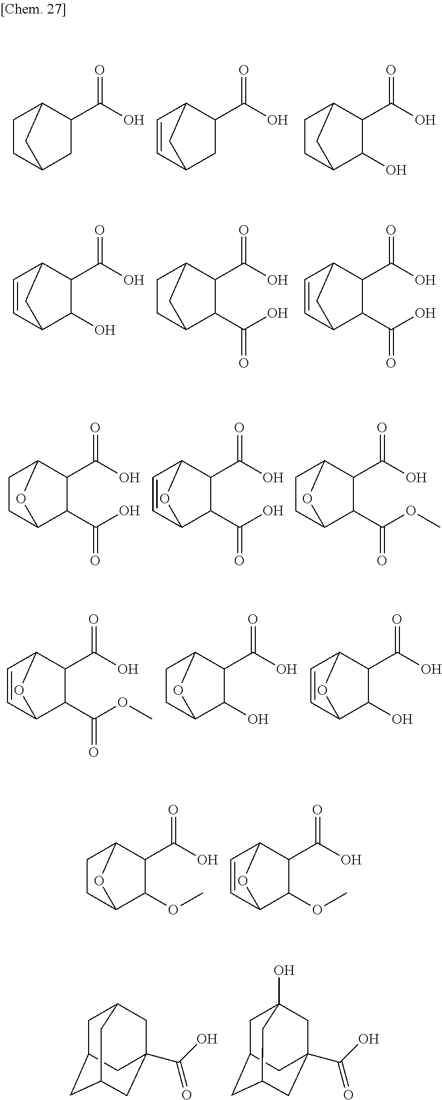

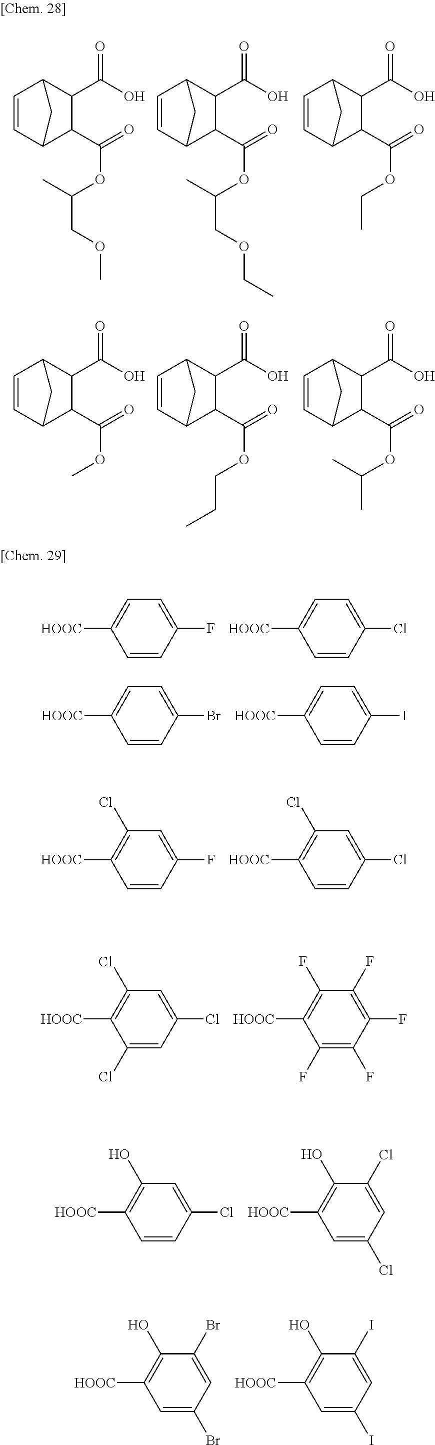

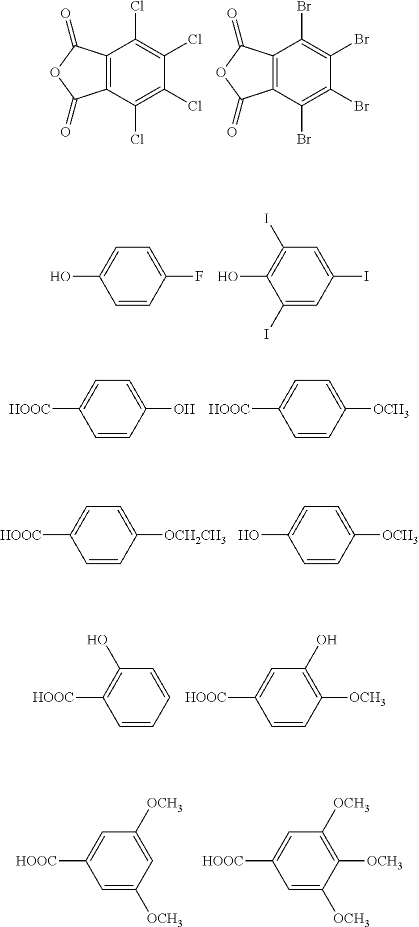

The polymer (A) may have a “an acyclic aliphatic hydrocarbon group which may be interrupted by a group containing a heteroatom and may be substituted with a substituent” at an end.

The acyclic aliphatic hydrocarbon group refers to a linear or branched alkyl group, a linear or branched alkenyl group, a linear or branched alkynyl group, and any combination thereof. The number of carbon atoms in the acyclic aliphatic hydrocarbon group is preferably less than 12, and more preferably less than 10.

Examples of the alkyl group include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, an undecyl group, a dodecyl group, a tridecyl group, a tetradecyl group, a pentadecyl group, a hexadecyl group, a heptadecyl group, an octadecyl group, a nonadecyl group, and an icodecyl group.

Examples of the alkenyl group include a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

Examples of the alkynyl group include an ethynyl group, a 1-propynyl group, and a 2-propynyl group.

The heteroatom is not particularly limited, but is usually an oxygen atom, a sulfur atom, or a nitrogen atom.

Examples of the group containing a heteroatom include an ether group, a thioether group, a carbonyl group, a thiocarbonyl group, an ester group, a thioester group, a thionoester group, an amide group, a urea group, and an oxysulfonyl group.

The phrase “may be interrupted by a group containing a heteroatom” means that one or two or more ether bonds, thioether bonds, carbonyl bonds, thiocarbonyl bonds, ester bonds, thioester bonds, thionoester bonds, amide bonds, urea bonds, oxysulfonyl bonds, and the like may be contained between a carbon-carbon bond of the acyclic aliphatic hydrocarbon group according to the present invention. When two or more bonds are contained, the number of types of bonds may be one or two or more.

Some specific examples of the group containing a heteroatom that interrupts the acyclic aliphatic hydrocarbon group are as shown in the following formulae. In the formulae, * represents a bond.

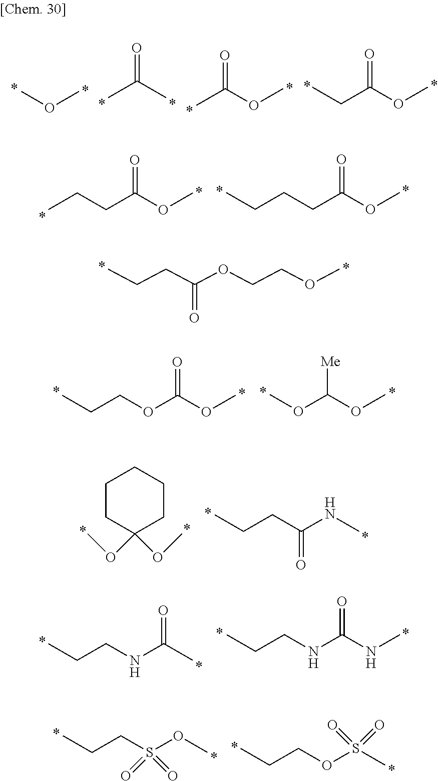

The phrase “may be substituted with a substituent” means that all or some of the hydrogen atoms of the acyclic aliphatic hydrocarbon group according to the present invention may be substituted with, for example, a hydroxy group, a linear or branched alkyl group having 1 to 10 carbon atoms, an alkoxy group having 1 to 20 carbon atoms, an acyloxy group having 1 to 10 carbon atoms, or a carboxy group.

The alkyl group is as described above.

Examples of the alkoxy group include a methoxy group, an ethoxy group, a n-propoxy group, an i-propoxy group, a n-butoxy group, an i-butoxy group, a s-butoxy group, a t-butoxy group, a n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, a cyclopentyloxy group, a cyclohexyloxy group, a norbornyloxy group, an adamantyloxy group, an adamantanemethyloxy group, an adamantaneethyloxy group, a tetracyclodecanyloxy group, and a tricyclodecanyloxy group.

The acyloxy group refers to a group represented by formula (20) below.

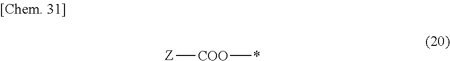

In formula (20), Z represents a hydrogen atom or an alkyl group having 1 to 9 carbon atoms in the alkyl group, and * represents a linking moiety with the acyclic aliphatic hydrocarbon group.

A heteroatom-containing acyclic aliphatic hydrocarbon group having less than 12 carbon atoms is preferred, an oxygen atom-containing acyclic aliphatic hydrocarbon group having less than 12 carbon atoms is more preferred, an acyclic aliphatic hydrocarbon group which has less than 12 carbon atoms and is interrupted by at least two types selected from the group consisting of an ether group, a carbonyl group, and an ester group is still more preferred, and an acyclic aliphatic hydrocarbon group which has less than 12 carbon atoms and is interrupted by an ether group and an ester group are most preferred.

The acyclic aliphatic hydrocarbon group preferably has at least one unsaturated bond (for example, a double bond or a triple bond). The acyclic aliphatic hydrocarbon group preferably has 1 to 3 unsaturated bonds. The unsaturated bond is preferably a double bond.

The “acyclic aliphatic hydrocarbon group which may be interrupted by a group containing a heteroatom and may be substituted with a substituent” can be derived, for example, by allowing an anhydride of a saturated or unsaturated dicarboxylic acid such as oxalic acid, malonic acid, succinic acid, glutaric acid, adipic acid, pimelic acid, suberic acid, azelaic acid, sebacic acid, maleic acid, methylmaleic acid, ethylmaleic acid, dimethylmaleic acid, or citraconic acid to react at the end of the polymer by a method known in itself.

An example of a method for producing the polymer (A) will be described.

The polymer (A) is obtained, for example, by the following reaction (I) or (II).

(I): A reaction of a compound represented by formula (1A) below and at least one of a compound represented by formula (2-1A) below and a compound represented by (2-2A) below

(II): A reaction of a compound represented by formula (1A) below, at least one of a compound represented by formula (2-1A) below and a compound represented by (2-2A) below, and a compound represented by formula (EA)

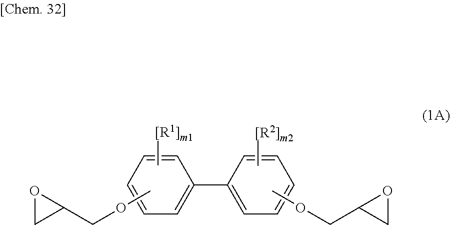

In formula (1A), R¹, R², m1, and m2 have the same meanings as R¹, R², m1, and m2 in formula (1), respectively.

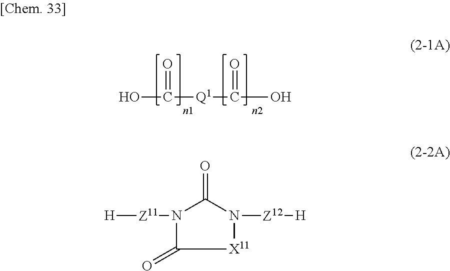

In formula (2-1A), Q¹, n1, and n2 have the same meanings as Q¹, n1, and n2 in formula (1-1), respectively.

In formula (2-2A), X¹¹, Z¹¹, and Z¹² have the same meanings as X¹¹, Z¹¹, and Z¹² in formula (1-2), respectively.

The reactions (I) and (II) may be carried out, for example, in the presence of a catalyst. The catalyst is, for example, a quaternary phosphonium salt such as tetrabutylphosphonium bromide or ethyltriphenylphosphonium bromide, or a quaternary ammonium salt such as benzyltriethylammonium chloride. As the amount of the catalyst used, an appropriate amount can be selected and used from the range of 0.1 to 10 mass % with respect to the total mass of the reaction raw material used in the reaction. As the temperature and time for the reaction, for example, optimum conditions can be selected from the range of 80 to 160° C. and 2 to 50 hours.

The molecular weight of the polymer (A) is not particularly limited.

The lower limit of the weight average molecular weight of the polymer (A) is, for example, 500, 1,000, 2,000, or 3,000.

The upper limit of the weight average molecular weight of the polymer (A) is, for example, 100,000, 50,000, or 30,000.

The content of the polymer (A) in the resist underlayer film-forming composition is not particularly limited, but is preferably 30 mass % to 95 mass %, more preferably 50 mass % to 90 mass %, and particularly preferably 60 mass % to 85 mass % with respect to the film constituent components in the resist underlayer film-forming composition.

The film constituent component refers to a component other than the solvent in the resist underlayer film-forming composition.

### <Solvent>

The solvent used in the resist underlayer film-forming composition is not particularly limited as long as it is a solvent capable of uniformly dissolving components such as the polymer (A), but an organic solvent generally used in a chemical solution for a semiconductor lithography process is preferred. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N, N-dimethylformamide, and N, N-dimethylacetamide. One of these solvents can be used alone, or two or more of these solvents can be used in combination.

Among these solvents, propylene glycol monomethyl ether, propylene glycol monomethyl ether acetate, ethyl lactate, butyl lactate, and cyclohexanone are preferred. In particular, propylene glycol monomethyl ether and propylene glycol monomethyl ether acetate are preferred.

### <Crosslinking Agent>

The resist underlayer film-forming composition may contain a crosslinking agent.

The crosslinking agent is not particularly limited.

Examples of the crosslinking agent include a compound having two or more structures represented by formula (C) below.

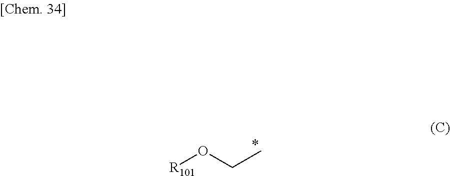

In formula (C), R₁₀₁ represents a hydrogen atom, an alkyl group having 1 to 4 carbon atoms, or an alkoxyalkyl group having 2 to 6 carbon atoms, and * represents a bond.

The bond is bonded to, for example, a nitrogen atom, a carbon atom constituting an aromatic hydrocarbon ring, or the like.

As R₁₀₁, a hydrogen atom, a methyl group, an ethyl group, or a group represented by the following structure is preferred.

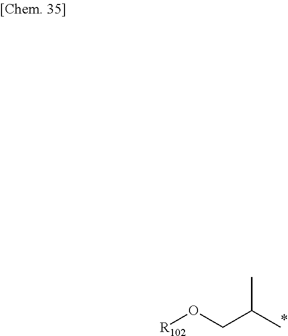

In the structure, R₁₀₂ represents a hydrogen atom, a methyl group, or an ethyl group, and * represents a bond.

The crosslinking agent is preferably a melamine compound, a guanamine compound, a glycoluril compound, a urea compound, or a compound having a phenolic hydroxy group. One of these can be used alone, or two or more of these can be used in combination.

The melamine compound is not particularly limited as long as it is a melamine compound having a group capable of reacting with a hydroxy group.

Examples of the melamine compound include hexamethylolmelamine, hexamethoxymethylmelamine, a compound in which 1 to 6 methylol groups of hexamethylolmelamine are methoxymethylated or a mixture thereof, hexamethoxyethylmelamine, hexaacyloxymethylmelamine, and a compound in which 1 to 6 methylol groups of hexamethylolmelamine are acyloxymethylated or a mixture thereof.

The guanamine compound is not particularly limited as long as it is a guanamine compound having a group capable of reacting with a hydroxy group.

Examples of the guanamine compound include tetramethylolguanamine, tetramethoxymethylguanamine, a compound in which 1 to 4 methylol groups of tetramethylolguanamine are methoxymethylated or a mixture thereof, tetramethoxyethylguanamine, tetraacyloxyguanamine, and a compound in which 1 to 4 methylol groups of tetramethylolguanamine are acyloxymethylated or a mixture thereof.

The glycoluril compound is not particularly limited as long as it is a glycoluril compound having a group capable of reacting with a hydroxy group.

Examples of the glycoluril compound include tetramethylolglycoluril, tetramethoxyglycoluril, tetramethoxymethylglycoluril, a compound in which 1 to 4 methylol groups of tetramethylolglycoluril are methoxymethylated or a mixture thereof, and a compound in which 1 to 4 methylol groups of tetramethylolglycoluril are acyloxymethylated or a mixture thereof.

The glycoluril compound may be, for example, a glycoluril derivative represented by formula (1E) below.

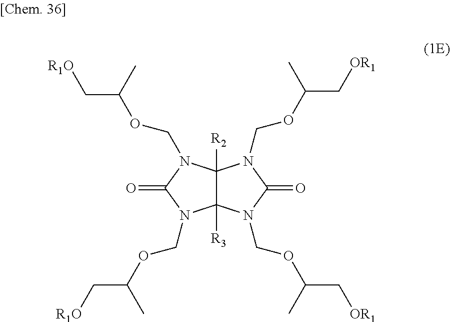

In formula (1E), four R₁'s each independently represent a methyl group or an ethyl group, and R₂ and R₃ each independently represent a hydrogen atom, an alkyl group having 1 to 4 carbon atoms, or a phenyl group.

Examples of the glycoluril derivative represented by formula (1E) include compounds represented by formula (1E-1) to formula (1E-6) below.

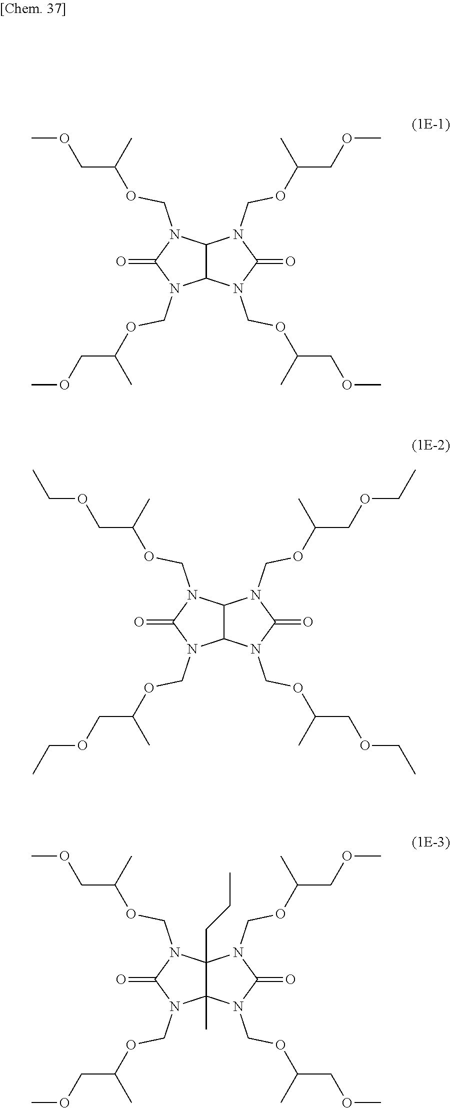

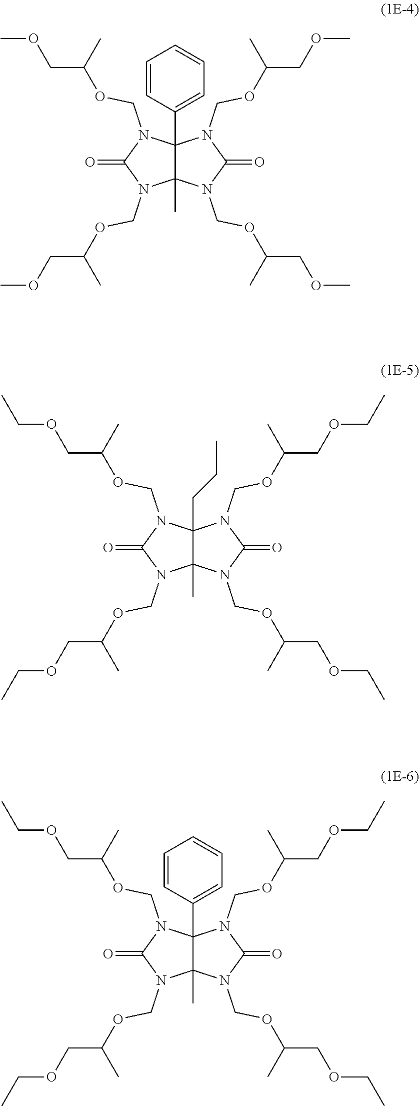

The glycoluril derivative represented by formula (1E) is obtained, for example, by allowing a glycoluril derivative represented by formula (2E) below to react with at least one compound represented by formula (3d) below.

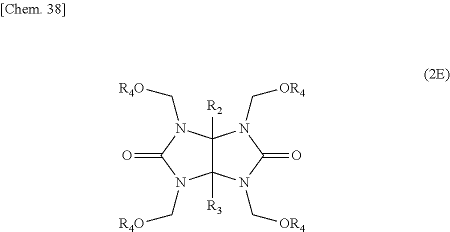

In formula (2E), R₂ and R₃ each independently represent a hydrogen atom, an alkyl group having 1 to 4 carbon atoms, or a phenyl group, and R₄'s each independently represent an alkyl group having 1 to 4 carbon atoms.

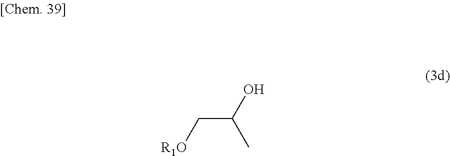

In formula (3d), R₁ represents a methyl group or an ethyl group.

Examples of the glycoluril derivative represented by formula (2E) include compounds represented by formula (2E-1) to formula (2E-4) below. Further, examples of the compound represented by formula (3d) include compounds represented by formula (3d-1) and formula (3d-2) below.

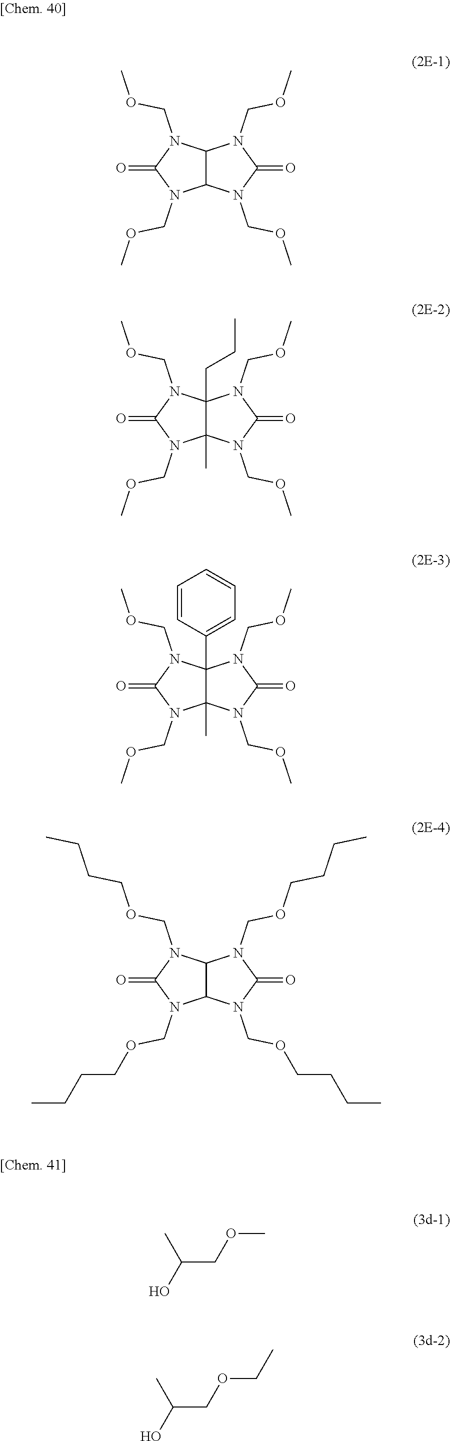

The urea compound is not particularly limited as long as it is a urea compound having a group capable of reacting with a hydroxy group.

Examples of the urea compound include tetramethylolurea, tetramethoxymethylurea, a compound in which 1 to 4 methylol groups of tetramethylolurea are methoxymethylated or a mixture thereof, and tetramethoxyethylurea.

Examples of the compound having a phenolic hydroxy group include a compound represented by formula (111) or formula (112) below.

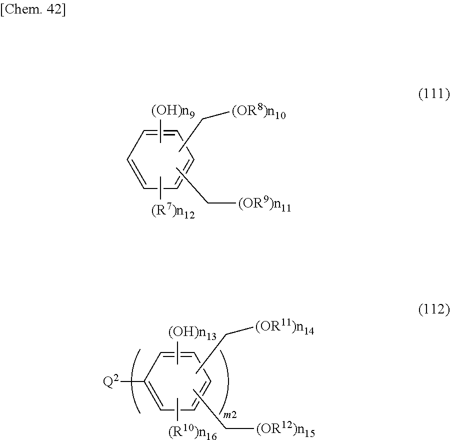

In formula (111) and formula (112), Q² represents a single bond or an m2-valent organic group,
R⁸, R⁹, R¹¹, and R¹² each represent a hydrogen atom or a methyl group,
R⁷ and R¹⁰ each represent an alkyl group having 1 to 10 carbon atoms or an aryl group having 6 to 40 carbon atoms,
n₉ represents an integer of 1≤n₉≤3, n₁₀ represents an integer of 2≤n₁₀≤5, n₁₁ represents an integer of 0≤n₁₁≤3, and n₁₂ represents an integer of 0≤n₁₂≤3, satisfying 3≤(n₉+n₁₀+n₁₁+n₁₂)≤6, n₁₃ represents an integer of 1≤n₁₃≤3, n₁₄ represents an integer of 1≤n₁₄≤4, n₁₅ represents an integer of 0≤n₁₅≤3, and n₁₆ represents an integer of 0≤n₁₆≤3, satisfying 2≤(n13+n₁₄+n₁₅+n₁₆)≤5, and m2 represents an integer of 2 to 10.

Examples of the m2-valent organic group in Q include an m2-valent organic group having 1 to 4 carbon atoms.

Examples of the compound represented by formula (111) or formula (112) include the following compounds.

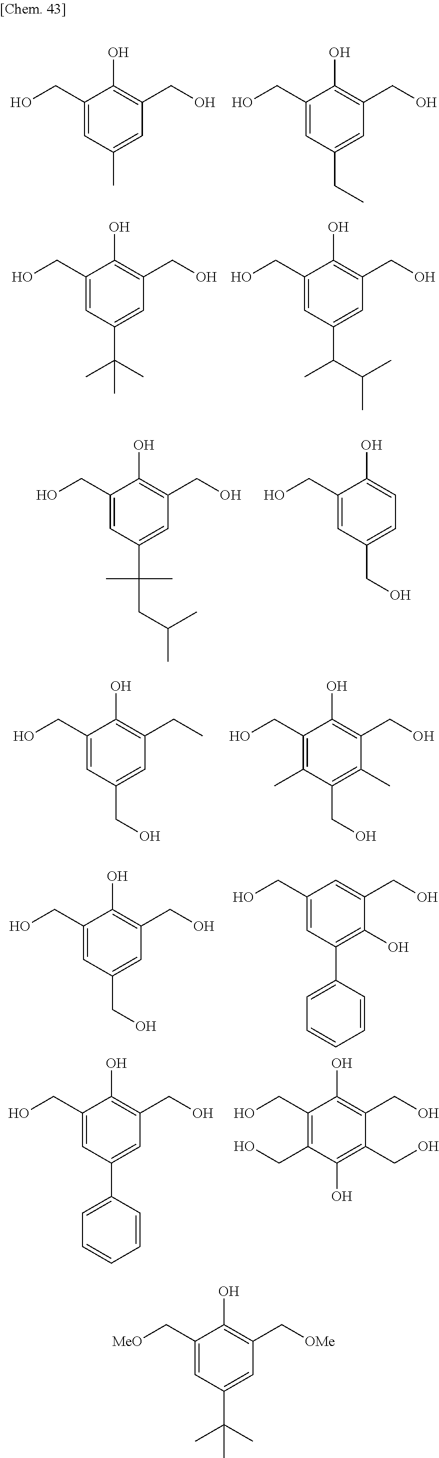

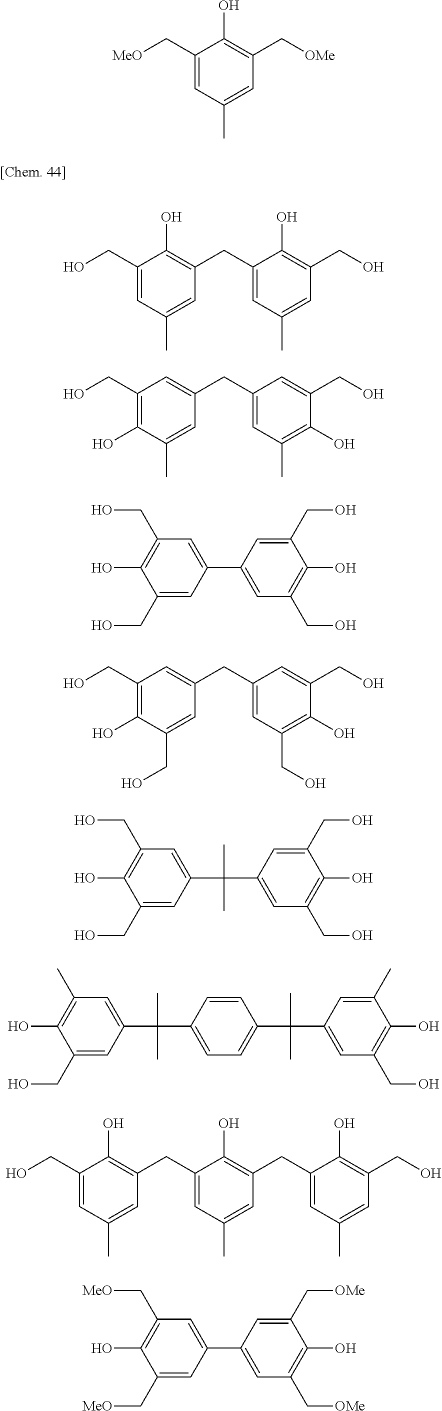

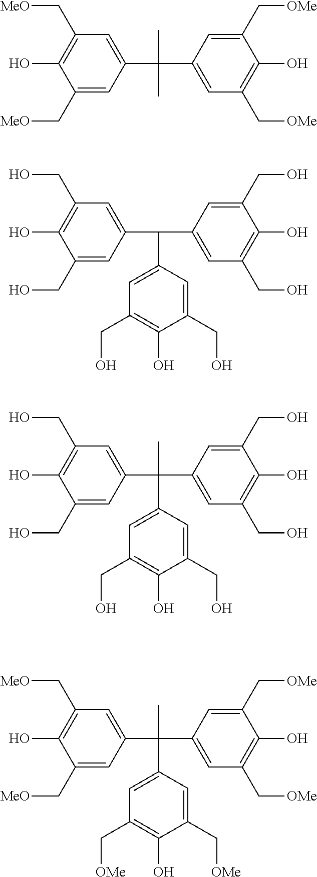 [SMILES: COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The compound can be obtained as a product of ASAHI YUKIZAI CORPORATION, and Honshu Chemical Industry Co., Ltd. Examples of the product include TMOM-BP (trade name) manufactured by ASAHI YUKIZAI CORPORATION.

Among them, a glycoluril compound is preferred, and specifically, tetramethylolglycoluril, tetramethoxyglycoluril, tetramethoxymethylglycoluril, a compound in which 1 to 4 methylol groups of tetramethylolglycoluril are methoxymethylated or a mixture thereof, or a compound in which 1 to 4 methylol groups of tetramethylolglycoluril are acyloxymethylated or a mixture thereof is preferred, and tetramethoxymethylglycoluril is preferred.

The molecular weight of the crosslinking agent is not particularly limited, but is preferably 500 or less.

The content of the crosslinking agent in the resist underlayer film-forming composition is not particularly limited, but is, for example, 1 mass % to 50 mass %, preferably 5 mass % to 40 mass % with respect to the polymer (A).

### <Curing Catalyst>

As the curing catalyst contained as an optional component in the resist underlayer film-forming composition, either of a thermal acid generator and a photoacid generator can be used, but it is preferred to use a thermal acid generator.

Examples of the thermal acid generator include sulfonic acid compounds and carboxylic acid compounds such as p-toluenesulfonic acid, trifluoromethanesulfonic acid, pyridinium p-toluenesulfonate (pyridinium p-toluenesulfonic acid), pyridinium phenolsulfonate, pyridinium p-hydroxybenzenesulfonate (p-phenolsulfonic acid pyridinium salt), pyridinium trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, hydroxybenzoic acid, N-methylmorpholine-p-toluenesulfonic acid, N-methylmorpholine-p-hydroxybenzenesulfonic acid, and N-methylmorpholine-5-sulfosalicylic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl p-toluenesulfonyl diazomethane.

Only one type of curing catalyst can be used, or two or more types thereof can be used in combination.

When a curing catalyst is used, the content ratio of the curing catalyst is, for example, 0.1 mass % to 50 mass %, preferably 1 mass % to 30 mass % with respect to the crosslinking agent.

### <Other Components>

In the resist underlayer film-forming composition, a surfactant can be further added in order to further improve the coating property against surface unevenness without formation of pinholes, striations, or the like.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (trade name, manufactured by Tochem Products Co., Ltd.), MEGAFAC F171, F173, and R-30 (trade name, manufactured by DIC Corporation), Fluorad FC430 and FC431 (trade name, manufactured by Sumitomo 3M Limited), Asahi Guard AG710, Surflon S-382, SC101, SC102, SC103, SC104, SC105, and SC106 (trade name, manufactured by AGC Corporation), and an organosiloxane polymer KP341 (manufactured by Shin-Etsu Chemical Co., Ltd.).

The blending amount of such a surfactant is usually 2.0 mass % or less, and preferably 1.0 mass % or less with respect to the total solid content of the resist underlayer film-forming composition.

One of these surfactants may be added alone, or two or more of these surfactants can be added in combination.

The solid content contained in the resist underlayer film-forming composition of the present invention, that is, the components excluding the solvent is, for example, 0.01 mass % to 10 mass %.

### (Resist Underlayer Film)

The resist underlayer of the present invention is a cured product of the resist underlayer film-forming composition described above.

The resist underlayer film can be produced, for example, by applying the resist underlayer film-forming composition described above onto a semiconductor substrate and baking the composition.

Examples of the semiconductor substrate coated with the resist underlayer film-forming composition include a silicon wafer, a germanium wafer, and a compound semiconductor wafer of gallium arsenide, indium phosphide, gallium nitride, indium nitride, aluminum nitride, or the like.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The resist underlayer film-forming composition of the present invention is applied onto such a semiconductor substrate by an appropriate application method such as a spinner or a coater. Thereafter, the composition is baked using a heating unit such as a hot plate to form a resist underlayer film. The baking conditions are appropriately selected from the baking temperature of 100° C. to 400° C. and from the baking time of 0.3 minutes to 60 minutes. It is preferred that the baking temperature is 120° C. to 350° C. and the baking time is 0.5 minutes to 30 minutes, and it is more preferred that the baking temperature is 150° C. to 300° C. and the baking time is 0.8 minutes to 10 minutes.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

The method of measuring the film thickness of the resist underlayer film in the present description is as follows.
Measuring device name: ellipsometric film thickness measurement system RE-3100 (SCREEN Semiconductor Solutions Co., Ltd.)
Single wavelength ellipsometer (SWE) mode
Arithmetic average of measurements at 8 points (for example, measurement is made at 8 points at intervals of 1 cm in X direction of wafer)

### (Laminate)

The laminate of the present invention includes a semiconductor substrate and the resist underlayer film of the present invention.

Examples of the semiconductor substrate include semiconductor substrates described above.

The resist underlayer film is disposed, for example, on the semiconductor substrate.

### (Method for Producing Semiconductor Element, and Pattern Forming Method)

The method for producing a semiconductor element of the present invention includes at least the following steps.
a step of forming a resist underlayer film on a semiconductor substrate using the resist underlayer film-forming composition of the present invention, and
a step of forming a resist film on the resist underlayer film

The pattern forming method of the present invention includes at least the following steps.
a step of forming a resist underlayer film on a semiconductor substrate using the resist underlayer film-forming composition of the present invention,
a step of forming a resist film on the resist underlayer film
a step of irradiating the resist film with EB or EUV, and then developing the resist film to obtain a resist pattern, and
a step of etching the resist underlayer film using the resist pattern as a mask

Usually, a resist film is formed on the resist underlayer film.

The film thickness of the resist film is preferably 200 nm or less, more preferably 150 nm or less, still more preferably 100 nm or less, and particularly preferably 80 nm or less. Further, the film thickness of the resist film is preferably 10 nm or more, more preferably 20 nm or more, and particularly preferably 30 nm or more.

A resist film formed on the resist underlayer film by a known method (for example, application and baking) is not particularly limited as long as the resist film responds to EB or EUV used for irradiation. Both a negative photoresist and a positive photoresist can be used.

In the present description, a resist responding to EB is also referred to as a photoresist.

Examples of the photoresist include a positive photoresist made of a novolac resin and 1,2-naphthoquinonediazide sulfonic acid ester, a chemically amplified photoresist made of a binder having a group, which is decomposed by an acid to increase the alkali dissolution rate, and a photoacid generator, a chemically amplified photoresist made of a low molecular compound, which is decomposed by an acid to increase the alkali dissolution rate of the photoresist, an alkali-soluble binder, and a photoacid generator, a chemically amplified photoresist made of a binder having a group, which is decomposed by an acid to increase the alkali dissolution rate, a low molecular compound, which is decomposed by an acid to increase the alkali dissolution rate of the photoresist, and a photoacid generator, and a resist containing a metal element. Examples thereof include V146G (trade name) manufactured by JSR Corporation, APEX-E (trade name) manufactured by Shipley Company, Inc., PAR710 (trade name) manufactured by Sumitomo Chemical Co., Ltd., and AR2772 and SEPR430 (trade names) manufactured by Shin-Etsu Chemical Co., Ltd. Further, examples thereof include fluorine atom-containing polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

Further, a resist composition, a radiation-sensitive resin composition, a so-called resist composition such as a high-resolution patterning composition based on an organometallic solution, and a metal-containing resist composition described in the following documents can be used, but not limited thereto: WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, and JP 2011-253185 A.

Examples of the resist composition include the following compositions.

An active ray-sensitive or radiation-sensitive resin composition that contains a resin A including a repeating unit having an acid decomposable group in which a polar group is protected by a protecting group to be removed by the action of an acid, and that contains a compound represented by general formula (121) below.

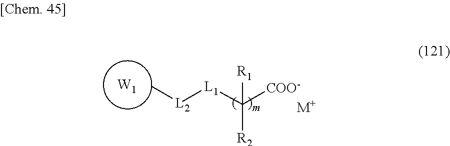

In general formula (121), m represents an integer of 1 to 6.

R₁ and R₂ each independently represent a fluorine atom or a perfluoroalkyl group.
L₁ represents —O—, —S—, —COO—, —SO₂—, or —SO₃—.
L₂ represents an alkylene group which may have a substituent or a single bond.
W₁ represents a cyclic organic group which may have a substituent.
M⁺ represents a cation.

A metal-containing film-forming composition for use in extreme ultraviolet light or electron beam lithography, which contains a compound having a metal-oxygen covalent bond, and a solvent, and in which a metal element constituting the compound belongs to periods 3 to 7 of groups 3 to 15 of the periodic table.

A radiation-sensitive resin composition that contains a polymer having a first structural unit represented by formula (31) below and a second structural unit represented by formula (32) below and containing an acid-dissociable group, and that contains an acid generator.

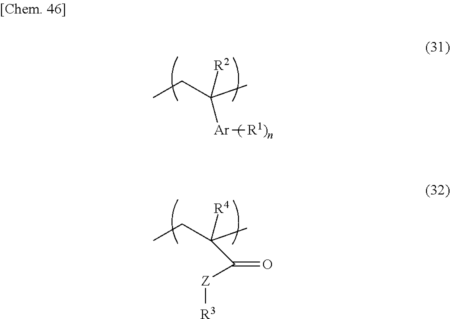

In formula (31), Ar is a group obtained by removing (n+1) hydrogen atoms from an arene having 6 to 20 carbon atoms, R¹ is a hydroxy group, a sulfanyl group, or a monovalent organic group having 1 to 20 carbon atoms, n is an integer of 0 to 11, when n is 2 or more, a plurality of R¹'s are identical or different, and R² is a hydrogen atom, a fluorine atom, a methyl group, or a trifluoromethyl group. In formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition that contains a resin (A1) including a structural unit having a cyclic carbonate structure, a structural unit represented by a formula below, and a structural unit having an acid-unstable group, and that contains an acid generator.

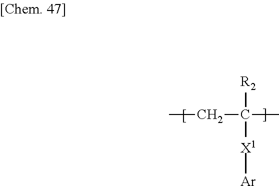

In the formula,

R² represents an alkyl group which has 1 to 6 carbon atoms and may have a halogen atom, a hydrogen atom, or a halogen atom, X¹ represents a single bond, —CO—O—*, or —CO—NR⁴—* where * represents a bond to —Ar, R⁴ represents a hydrogen atom or an alkyl group having 1 to 4 carbon atoms, and Ar represents an aromatic hydrocarbon group which has 6 to 20 carbon atoms and may have one or more groups selected from the group consisting of a hydroxy group and a carboxyl group.

Examples of the resist film include the following.

A resist film containing a base resin including a repeating unit represented by formula (a1) below and/or a repeating unit represented by formula (a2) below, and a repeating unit which generates an acid bonded to a polymer main chain by exposure.

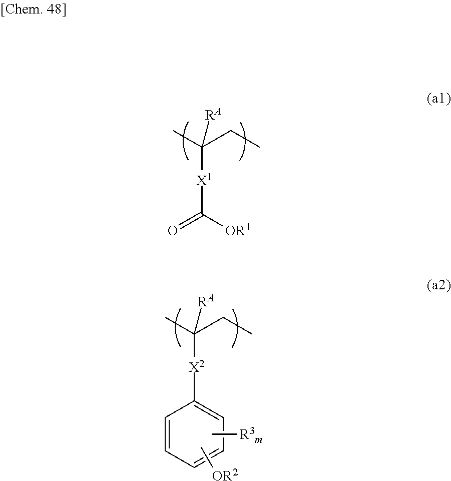

In formula (a1) and formula (a2), R^{A}'s are each independently a hydrogen atom or a methyl group, R¹ and R² are each independently a tertiary alkyl group having 4 to 6 carbon atoms, R³'s are each independently a fluorine atom or a methyl group, m is an integer of 0 to 4, X¹ is a single bond, a phenylene group, or a naphthylene group, or a linking group having 1 to 12 carbon atoms containing at least one selected from an ester bond, a lactone ring, a phenylene group, and a naphthylene group, and X² is a single bond, an ester bond, or an amide bond.

Examples of a resist material include the following.

A resist material containing a polymer having a repeating unit represented by formula (b1) or formula (b2) below.

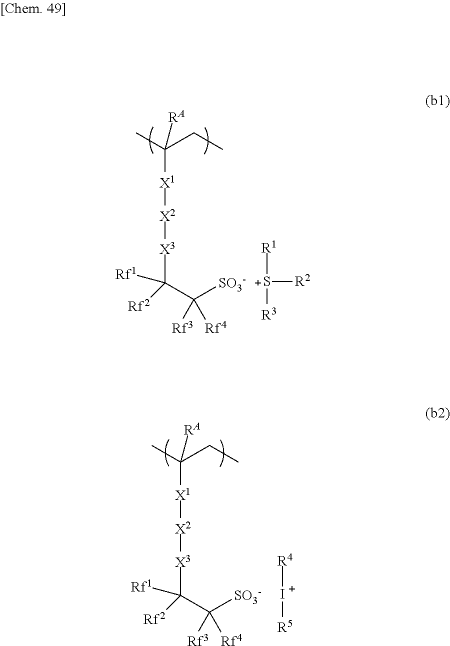

In formula (b1) and formula (b2), R^{A} is a hydrogen atom or a methyl group, X¹ is a single bond or an ester group, X² is a linear, branched, or cyclic alkylene group having 1 to 12 carbon atoms or an arylene group having 6 to 10 carbon atoms, and a methylene group constituting the alkylene group may be partially substituted with an ether group, an ester group, or a lactone ring-containing group, and at least one hydrogen atom contained in X² is substituted with a bromine atom, X³ is a single bond, an ether group, an ester group, or a linear, branched, or cyclic alkylene group having 1 to 12 carbon atoms, and a methylene group constituting the alkylene group may be partially substituted with an ether group or an ester group, Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may be combined to form a carbonyl group, R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and methylene groups constituting these groups may be partially substituted with an ether group, an ester group, a carbonyl group, a carbonate group, or a sulfonic acid ester group, and R¹ and R² may be bonded to form a ring together with the sulfur atom to which R¹ and R² are bonded.

A resist material containing a base resin containing a polymer including a repeating unit represented by formula (a) below.

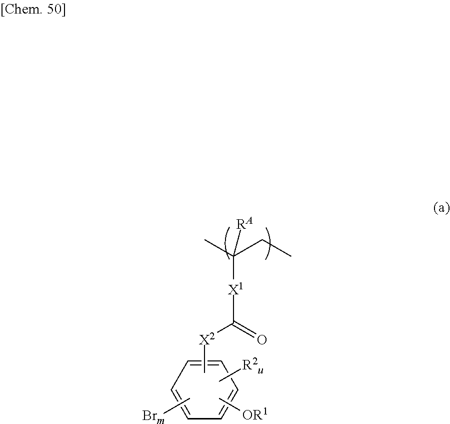

In formula (a), R^{A} is a hydrogen atom or a methyl group, R¹ is a hydrogen atom or an acid-unstable group, R² is a linear, branched, or cyclic alkyl group having 1 to 6 carbon atoms or a halogen atom other than bromine, X¹ is a single bond or a phenylene group, or a linear, branched, or cyclic alkylene group which has 1 to 12 carbon atoms and may contain an ester group or a lactone ring, X² is —O—, —O—CH₂—, or —NH—, m is an integer of 1 to 4, and u is an integer of 0 to 3, however, m+u is an integer of 1 to 4.

A resist composition, which generates an acid by exposure and changes its solubility in a developer by the action of an acid, and contains
a base material component (A) that changes its solubility in a developer by the action of an acid, and a fluorine additive component (F) that exhibits decomposability against an alkaline developer, and in which
the fluorine additive component (F) contains a fluororesin component (F1) having a constituent unit (f1) containing a base-dissociable group and a constituent unit (f2) containing a group represented by general formula (f2-r-1) below.

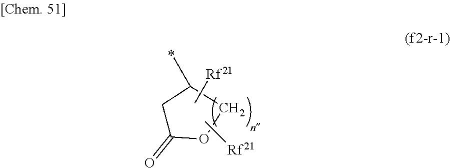

In formula (f2-r-1), Rf²¹'s are each independently a hydrogen atom, an alkyl group, an alkoxy group, a hydroxy group, a hydroxyalkyl group, or a cyano group, n″ is an integer of 0 to 2, and * is a bond.

The constituent unit (f1) includes a constituent unit represented by general formula (f1-1) below or a constituent unit represented by general formula (f1-2) below.

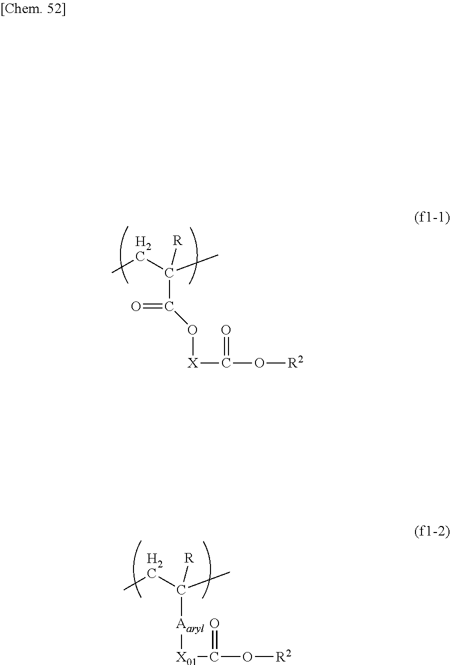

In formulae (f1-1) and (f1-2), R's are each independently a hydrogen atom, an alkyl group having 1 to 5 carbon atoms, or a halogenated alkyl group having 1 to 5 carbon atoms, X is a divalent linking group having no acid-dissociable site, A_{aryl} is a divalent aromatic cyclic group which may have a substituent, X₀₁ is a single bond or a divalent linking group, and R²'s are each independently an organic group having a fluorine atom.

Examples of a coating, a coating solution, and a coating composition include the following.

A coating containing a metal oxo-hydroxo network having an organic ligand through a metal-carbon bond and/or a metal-carboxylate bond.

An inorganic oxo/hydroxo-based composition.

A coating solution containing an organic solvent; a first organometallic composition represented by a formula R₂SnO_{(2-(z/2)-(x/2))}(OH)ₓ (where 0<z≤2 and 0<(z+x)≤4), a formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolysable metal compound represented by a formula MX′ᵥ (where M is a metal selected from groups 2 to 16 of the periodic table of elements, v=a number of 2 to 6, and X′ is a ligand having a hydrolysable M-X bond or a combination thereof).

A coating solution containing an organic solvent and a first organometallic compound represented by a formula RSnO_{(3/2-x/2)}(OH)ₓ (where 0<x<3), wherein the solution contains about 0.0025 M to about 1.5 M of tin and R is an alkyl group or a cycloalkyl group having 3 to 31 carbon atoms and the alkyl group or the cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The irradiation with EB or EUV is performed, for example, through a mask (reticle) for forming a predetermined pattern. The resist underlayer film-forming composition of the present invention is preferably applied for extreme ultraviolet (EUV) exposure.

The irradiation energy of an electron beam and the exposure amount of EUV are not particularly limited.

Bake (post exposure bake: PEB) may be performed after irradiation with EB or EUV and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

In the development, for example, an alkaline developer is used.

Examples of the development temperature include 5° C. to 50° C.

Examples of the developing time include 10 seconds to 300 seconds.

As the alkaline developer, for example, an aqueous solution of an inorganic alkali such as sodium hydroxide, potassium hydroxide, sodium carbonate, sodium silicate, sodium metasilicate, or aqueous ammonia, a primary amine such as ethylamine or n-propylamine, a secondary amine such as diethylamine or di-n-butylamine, a tertiary amine such as triethylamine or methyldiethylamine, an alcohol amine such as dimethylethanolamine or triethanolamine, a quaternary ammonium salt such as tetramethylammonium hydroxide, tetraethylammonium hydroxide, or choline, or a cyclic amine such as pyrrole or piperidine can be used. Further, the aqueous solution of an alkali can also be used by adding an appropriate amount of an alcohol such as isopropyl alcohol or a surfactant such as a nonionic surfactant thereto. Among these, a preferred developer is an aqueous solution of a quaternary ammonium salt, and more preferred developers are an aqueous solution of tetramethylammonium hydroxide and an aqueous solution of choline. Further, a surfactant or the like can also be added to these developers. It is also possible to use a method in which development is performed with an organic solvent such as butyl acetate in place of the alkaline developer and a portion where the alkali dissolution rate of the photoresist is not improved is developed.

Subsequently, the resist underlayer film is etched using the formed resist pattern as a mask. The etching may be dry etching or wet etching, but is preferably dry etching.

When the inorganic film is formed on the surface of a semiconductor substrate used, the surface of the inorganic film is exposed, and when the inorganic film is not formed on the surface of a semiconductor substrate used, the surface of the semiconductor substrate is exposed. Thereafter, the semiconductor substrate is subjected to a step of processing the semiconductor substrate by a known method (a dry etching method or the like), whereby a semiconductor element can be produced.

### EXAMPLES

Next, the contents of the present invention will be specifically described with reference to examples, but the present invention is not limited thereto.

The weight average molecular weight of each of the polymers shown in the following Synthesis Examples 1 to 3 and Comparative Synthesis Examples 1 and 2 in the present description is a measurement result by gel permeation chromatography (hereinafter abbreviated as GPC). In the measurement, a GPC apparatus manufactured by Tosoh Corporation was used, and measurement conditions and the like are as follows.
GPC column: ShodexGF-310HQ, Shodex GF-510HQ, Shodex GF-710HQ [registered trademark] (Showa Denko K.K.)
Column temperature: 40° C.
Solvent: N, N-dimethylformamide (DMF)
Flow rate: 0.6 m1/min
Standard sample: polystyrene (manufactured by Tosoh Corporation)

### Synthesis Example 1

To 31.01 g of propylene glycol monomethyl ether, 4.00 g of 3,3′,5,5′-tetramethylbiphenyl diglycidyl ether (manufactured by Mitsubishi Chemical Corporation), 3.48 g of bis(3,5-dimethyl-4-hydroxyphenyl) sulfone (manufactured by Tokyo Chemical Industry Co., Ltd.), and 0.28 g of tetrabutylphosphonium bromide (manufactured by Hokko Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, a polymer 1 obtained had a weight average molecular weight of 22, 600 in terms of standard polystyrene and a dispersity of 3.4. The structure present in the polymer 1 is represented by a formula below.

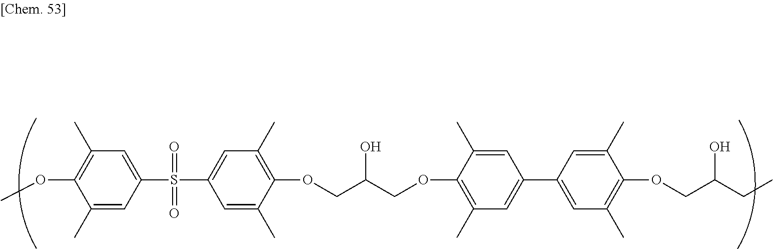

### Synthesis Example 2

To 12.13 g of propylene glycol monomethyl ether, 4.00 g of 3,3′,5,5′-tetramethylbiphenyl diglycidyl ether (manufactured by Mitsubishi Chemical Corporation), 3.81 g of 2,2-bis(4-hydroxyphenyl) hexafluoropropane (manufactured by Tokyo Chemical Industry Co., Ltd.), and 0.28 g of tetrabutylphosphonium bromide (manufactured by Hokko Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, a polymer 2 obtained had a weight average molecular weight of 22,000 in terms of standard polystyrene and a dispersity of 2.8. The structure present in the polymer 2 is represented by a formula below.

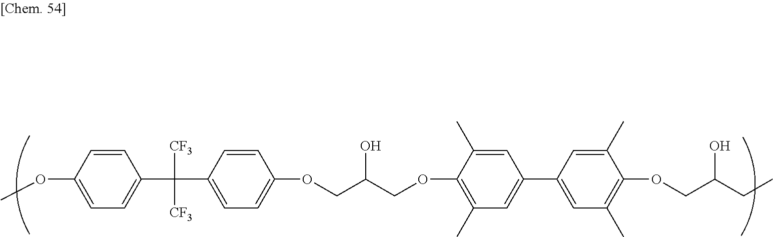

### Synthesis Example 3

To 29.53 g of propylene glycol monomethyl ether, 7.00 g of 3,3′,5,5′-tetramethylbiphenyl diglycidyl ether (manufactured by Mitsubishi Chemical Corporation), 2.96 g of diethyl barbital (manufactured by Yashiro Pharmaceutical Co., Ltd.), 2.21 g of 3,5-diiodosalicylic acid (manufactured by Tokyo Chemical Industry Co., Ltd.), and 0.48 g of tetrabutylphosphonium bromide (manufactured by Hokko Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, a polymer 3 obtained had a weight average molecular weight of 5,600 in terms of standard polystyrene and a dispersity of 2.3. The structure present in the polymer 3 is represented by a formula below.

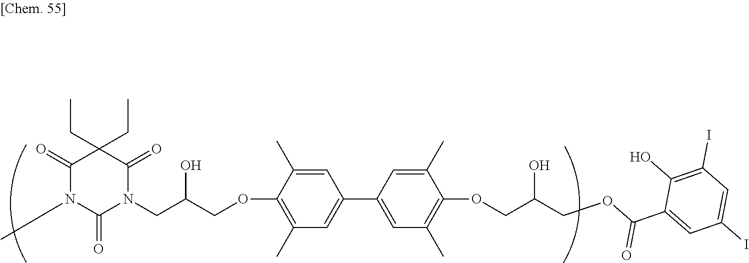

### Comparative Synthesis Example 1

To 45.45 g of cyclohexanone, 5.00 g of monoallyl diglycidyl isocyanurate (manufactured by Shikoku Chemicals Corporation), 5.75 g of bis(3,5-dimethyl-4-hydroxyphenyl) sulfone (manufactured by Tokyo Chemical Industry Co., Ltd.), 0.16 g of 2,6-di-tert-butyl-p-cresol (manufactured by Tokyo Chemical Industry Co., Ltd.), and 0.46 g of tetrabutylphosphonium bromide (manufactured by Hokko Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, a polymer 4 obtained had a weight average molecular weight of 16,200 in terms of standard polystyrene and a dispersity of 2.9. The structure present in the polymer 4 is represented by a formula below.

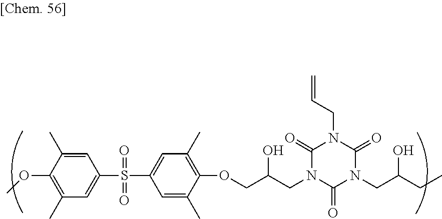

### Comparative Synthesis Example 2

To 26.56 g of propylene glycol monomethyl ether, 9.00 g of monoallyl diglycidyl isocyanurate (manufactured by Shikoku Chemicals Corporation), 11.36 g of 2,2-bis(4-hydroxyphenyl) hexafluoropropane (manufactured by Tokyo Chemical Industry Co., Ltd.), 0.28 g of 2,6-di-tert-butyl-p-cresol (manufactured by Tokyo Chemical Industry Co., Ltd.), and 1.09 g of tetrabutylphosphonium bromide (manufactured by Hokko Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, a polymer 5 obtained had a weight average molecular weight of 17,500 in terms of standard polystyrene and a dispersity of 2.4. The structure present in the polymer 5 is represented by a formula below.

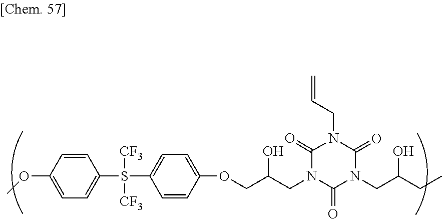

### (Preparation of Resist Underlayer Film-Forming Composition)

Each of the polymers obtained in Synthesis Examples 1 and 2 and Comparative Synthesis Examples 1 and 2, a crosslinking agent, a curing catalyst, a surfactant, and a solvent were mixed in the proportions shown in Tables 1-1 and 1-2, and the mixture was filtered through a 0.1 μm fluororesin filter to prepare each resist underlayer film-forming composition.

The meanings of the abbreviations in Tables 1-1 and 1-2 are as follows.
PGME-PL: Imidazo[4,5-d]imidazole-2,5(1H,3H)-dione, tetrahydro-1,3,4,6-tetrakis[(2-methoxy-1-methylethoxy)methyl]-
PyPSA: pyridinium p-hydroxybenzenesulfonate
PGMEA: propylene glycol monomethyl ether acetate
PGME: propylene glycol monomethyl ether
Cy: cyclohexanone

Each addition amount was expressed in parts by mass.

The addition proportion of a polymer in Tables 1-1 and 1-2 indicates the addition amount of the polymer itself, not the addition amount of the polymer solution.

TABLE 1-1

| | | Crosslinking | Curing | | |
|---|---|---|---|---|---|
| | Polymer | agent | catalyst | Solvent | |
| Example 1 | Synthesis | PGME-PL | PyPSA | PGME | PGMEA |
| | Example 1 | | | | |
| (parts by | 0.15 | 0.04 | 0.01 | 90 | 10 |
| mass) | | | | | |
| Example 2 | Synthesis | PGME-PL | PyPSA | PGME | PGMEA |
| | Example 2 | | | | |
| (parts by | 0.15 | 0.04 | 0.01 | 90 | 10 |
| mass) | | | | | |

TABLE 1-2

| | | Crosslinking | Curing | | |
|---|---|---|---|---|---|
| | Polymer | agent | catalyst | Solvent | |
| Comparative | Comparative | PGME-PL | PyPSA | PGME | Cy |
| Example 1 | Synthesis | | | | |
| | Example 1 | | | | |
| (parts by | 0.15 | 0.04 | 0.01 | 10 | 90 |
| mass) | | | | | |
| Comparative | Comparative | PGME-PL | PyPSA | PGME | PGMEA |
| Example 2 | Synthesis | | | | |
| | Example 2 | | | | |
| (parts by | 0.15 | 0.04 | 0.01 | 90 | 10 |
| mass) | | | | | |

### (Elution Test in Photoresist Solvent)

Each of the resist underlayer film-forming compositions of Examples 1 and 2 and Comparative Examples 1 and 2 was applied onto a silicon wafer using a spinner. The silicon wafer was baked at 205° C. for 60 seconds on a hot plate to obtain a resist underlayer film having a film thickness of 5 nm. These resist underlayer films were immersed in a mixed solution of propylene glycol monomethyl ether/propylene glycol monomethyl ether acetate=70/30 (volume ratio), which is a solvent used for the photoresist, and a case where the film thickness change was 1 Å or less was evaluated as “good”, and a case where the film thickness change was more than 1 Å was evaluated as “poor”. The results are shown in Table 2.

### (Film Formability Test)

Each of the resist underlayer film-forming compositions of Examples 1 and 2 and Comparative Examples 1 and 2 was applied onto a silicon wafer using a spinner. The silicon wafer was baked at 205° C. for 60 seconds on a hot plate to obtain a resist underlayer film having a film thickness of 5 nm. The surface roughness (Sa) of each of these resist underlayer films was measured using an atomic force microscope (AFM), and a case where the surface roughness (Sa) was 3 Å or less was evaluated as “good”, and a case where the surface roughness (Sa) was more than 3 Å was evaluated as “poor”. The results are shown in Table 2.

TABLE 2

| | Elution test | Film formability |
|---|---|---|
| Example 1 | Good | Good |
| Example 2 | Good | Good |
| Comparative Example 1 | Good | Good |
| Comparative Example 2 | Good | Good |

### (Evaluation of Resist Patterning)

### [Test of Resist Pattern Formation by EUV Exposure System]

Each of the resist underlayer film-forming compositions of Examples 1 and 2 and Comparative Examples 1 and 2 was applied onto a silicon wafer using a spinner. The silicon wafer was baked at 205° C. for 60 seconds on a hot plate to obtain a resist underlayer film having a film thickness of 5 nm. A positive resist solution for EUV was applied onto the resist underlayer film by spin coating, followed by heating to 130° C. for 60 seconds to form an EUV resist film. The resist film was exposed to light under predetermined conditions using an EUV exposure system (NXE3400B). After the exposure, the film was baked (PEB) at 100° C. for 60 seconds, cooled on a cooling plate to room temperature, and subjected to paddle development for 30 seconds using a 2.38% aqueous tetramethylammonium hydroxide solution (NMD-3) as a photoresist developer. A resist pattern having a hole size of 17 nm to 20 nm was formed. A scanning electron microscope (CG6300 manufactured by Hitachi High-Technologies Corporation) was used for measuring the length of the resist pattern.

With respect to the photoresist pattern thus obtained, whether or not a contact hole (C/H) of 20 nm could be formed was evaluated. In all cases of Examples 1 and 2 and Comparative Examples 1 and 2, 20 nm C/H pattern formation was observed. Further, the EUV irradiation amount at which the 20 nm hole was formed was defined as the optimum irradiation energy and the irradiation energy (mJ/cm²) when the irradiation energy of each of Comparative Examples 1 and 2 is defined as 1.00 is shown in Table 3. In Examples 1 and 2, improvement in sensitivity as compared with Comparative Examples 1 and 2 was verified.

TABLE 3

| | Irradiation energy (mJ/cm²) |
|---|---|
| Example 1 | 0.99 |
| Example 2 | 0.99 |
| Comparative Example 1 | 1.00 |
| Comparative Example 2 | 1.00 |

1. A resist underlayer film-forming composition for use in EB or EUV lithography, the resist underlayer film-forming composition comprising a polymer having a structure represented by formula (1) below and a solvent: 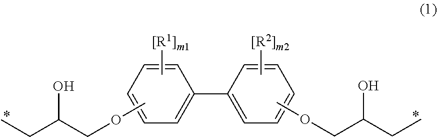
wherein R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different, and
* represents a bond.

2. The resist underlayer film-forming composition according to claim 1, wherein the polymer has a repeating unit represented by formula (1-1) below as a repeating unit having a structure represented by formula (1): 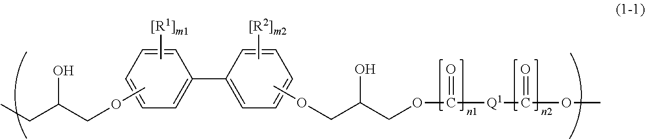
wherein R¹ and R² each independently represent an alkyl group which has 1 to 6 carbon atoms and may be substituted with a halogen atom, or a halogen atom,
m1 and m2 each independently represent an integer of 0 to 4,
when there are two or more R¹'s, the two or more R¹'s may be the same or different,
when there are two or more R²'s, the two or more R²'s may be the same or different,
Q¹ represents a divalent organic group having an aromatic hydrocarbon ring, and
n1 and n2 each independently represent 0 or 1.

3. The resist underlayer film-forming composition according to claim 2, wherein the Q¹ is represented by formula (1-1-1) below: 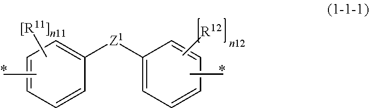
wherein Z¹ represents a single bond, an alkylene group which has 1 to 6 carbon atoms and may be substituted with a halogen atom, or a sulfonyl group,
R¹¹ and R¹² each independently represent an alkyl group which has 1 to 13 carbon atoms and may be substituted with a halogen atom, a hydroxy group, a methoxy group, a thiol group, an acetyl group, a nitro group, an allyl group, a phenyl group, a naphthyl group, or a halogen atom,
n11 and n12 each independently represent an integer of 0 to 4,
when there are two or more R¹¹'s, the two or more R¹¹'s may be the same or different, and
when there are two or more R¹²'s, the two or more R¹²'s may be the same or different.

4. The resist underlayer film-forming composition according to claim 1, wherein m1 and m2 are 1, and R¹ and R² are methyl groups.

5. The resist underlayer film-forming composition according to claim 1, further comprising a crosslinking agent.

6. The resist underlayer film-forming composition according to claim 5, wherein the crosslinking agent is a compound having two or more structures represented by formula (C) below: 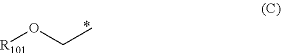
wherein R₁₀₁ represents a hydrogen atom, an alkyl group having 1 to 4 carbon atoms, or an alkoxyalkyl group having 2 to 6 carbon atoms, and * represents a bond.

7. A resist underlayer film which is a cured product of the resist underlayer film-forming composition according to claim 1.

8. A laminate, comprising:
a semiconductor substrate; and
the resist underlayer film according to claim 7.

9. A method for producing a semiconductor element, the method comprising steps of:
forming a resist underlayer film on a semiconductor substrate using the resist underlayer film-forming composition according to claim 1; and
forming a resist film on the resist underlayer film.

10. A pattern forming method, comprising steps of:
forming a resist underlayer film on a semiconductor substrate using the resist underlayer film-forming composition according to claim 1;
forming a resist film on the resist underlayer film;
irradiating the resist film with EB or EUV, and then developing the resist film to obtain a resist pattern; and
etching the resist underlayer film using the resist pattern as a mask.
